(19) United States
(12) Patent Application Publication
(10) Pub. No.: US 2026/0160284 A1
(43) Pub. Date: Jun. 11, 2026

(54) ABUTMENT STRUCTURE

(71) Applicant: DTECH PRECISION INDUSTRIES CO., LTD., New Taipei City (TW)

(72) Inventor: TING-JUI WANG

(73) Assignee: DTECH PRECISION INDUSTRIES CO., LTD., New Taipei City (TW)

(21) Appl. No.: 19/286,271

(22) Filed: Jul. 31, 2025

(30) Foreign Application Priority Data
Dec. 6, 2024 (TW) 113147545

(51) Int. Cl. F16B 2/18; H05K 7/14

(52) U.S. Cl. CPC F16B 2/185; H05K 7/1417

(57) ABSTRACT

The present disclosure provides an abutment structure and an abutment method thereof. The abutment structure includes a body, an abutment part, and a fastening part. The abutment part is movably arranged on the body. The abutment part abuts against the fastening part. According to the present disclosure, the abutment part can drive the fastening part to achieve the effect of limiting by abutment.

### CROSS-REFERENCE TO RELATED APPLICATION

This non-provisional application claims priority under 35 U.S.C. § 119(a) on Patent Application No(s). 113147545 filed in Taiwan, R.O.C. on Dec. 6, 2024, the entire contents of which are hereby incorporated by reference.

### BACKGROUND OF THE INVENTION

### 1. Field of the Invention

The present disclosure relates to an abutment structure, and in particular to an abutment structure in which an abutment part drives a fastening part to achieve the effect of limiting by abutment.

### 2. Description of the Related Art

When a general object is combined or limited, the lack of corresponding structural design makes it difficult for the object to smoothly achieve limiting by abutment.

### BRIEF SUMMARY OF THE INVENTION

In view of the above conventional technology, the inventor has developed an abutment structure in order to achieve the purpose of limiting by abutment.

The abutment structure and the abutment method thereof according to the present disclosure can achieve the purposes of smoother movement and limiting by abutment through the abutment structure.

In order to achieve the above purpose and other purposes, the present disclosure provides an abutment structure, which includes a body, at least one abutment part, and a fastening part. The abutment part is movably arranged on the body; the abutment part abuts against the fastening part, or the abutment part is configured to control or drive the movement or fastening of the fastening part.

In the abutment structure, the body is connected to an object, and the abutment part is configured to abut against a pushed object to allow the object to be aligned by abutment, move, elastically aligned, elastically move, limited, or elastically limited.

In the abutment structure, one end of the elastic component abuts against the body, and the other end of the elastic component abuts against a stop part connected to the abutment part.

In the abutment structure, the body is provided with a connecting part, and the connecting part is riveted, flared, welded, or locked to the object, or the connecting part is integrally formed with the object.

In the abutment structure, the abutment part is provided with a coupling part, and the coupling part is connected to the body.

In the abutment structure, the number of the abutment parts is two or more, and the abutment parts are arranged on two sides, at two ends, or at different positions of the object to abut against a pushed object.

In the abutment structure, the body is provided with a limiting part, and the limiting part restricts the movable combination of the abutment part and the body, or the limiting part is deformed to restrict the abutment part and the body.

In the abutment structure, the abutment part and the body are provided with limiting parts for combination.

In the abutment structure, the abutment part is located in a lateral direction of the body, or the abutment part is located on a lateral direction of an object.

In the abutment structure, the abutment structure or the abutment structure is joined to a pushed object to form a module, the abutment structure or the module is a handle, a rail, a sliding member, a moving object, a rod body, a rotating body, a heat sink, a shell, a printed circuit board or a telescopic structure, or the pushed object is a handle, a rail, a sliding member, a moving object, a rod body, a rotating body, a heat sink, a wheel moving body, a rail body, a cylindrical body, a chip, a fastening body, a handle body, a runner, a fluid barrier, a spoiler, a heat sink, a bracket body, a beam line body, a beam tube body, a beam fiber body, a wire body, a tube body, a fiber body, an elastic body, a shell, a printed circuit board or a telescopic structure.

In the abutment structure, the abutment structure is provided with an anti-rotating part, and the anti-rotating part and a corresponding anti-rotating part of the object prevent each other from rotating, limit or restrict the direction of the object, or the body of the abutment structure is provided with a connecting part and an anti-rotating part, the connecting part is joined to the object, and the anti-rotating part and the corresponding anti-rotating part of the object prevent each other from rotating, limit or restrict the direction of the object.

In the abutment structure, the body is configured to be welded, riveted, flared, fastened, or locked to or integrally formed with the object.

In the abutment structure, the body is provided with an arrangement part for allowing the fastening part to pass through and reach an arrangement position, or further allow the abutment part to be assembled on or penetrate through the body, or allowing the abutment part to control the fastening part.

In the abutment structure, the body is provided with an arrangement part to allow the fastening part to pass through and reach an arrangement position, or configured to be joined to the body through a joining part, or the joining part is the abutment part for abutting against the fastening part, or the abutment part is configured to abut against the fastening part, or the abutment part moves to control the movement or fastening of the fastening part, or the joining part is joined to the abutment part through another joining part, or the another joining part moves to control the movement or fastening of the fastening part, or the abutment part drives the another joining part to move to control the movement or fastening of the fastening part, or where the fastening part is a spherical body, an inclined surface body, a one-way inclined surface body, a cylindrical body or a fastening body, or the arrangement part is a through hole, a movement space or groove, an inclined surface part, a stepped part, an arc surface part, a right-angled part or a non-right-angled part, or the abutment part is another fastening part, or the joining part is another fastening part, or the abutment part is the fastening part, or the joining part is the fastening part, or where the abutment part and the joining part are integrally formed, or where the abutment part and the joining part are connected to each other, or where the abutment part is a joining part, or where the fastening part reaches the arrangement position by free fall, or where the fastening part reaches the arrangement position under the help of a tool or a magnetic tool.

In the abutment structure, the abutment structure further includes a joining part configured to be joined to the body, or the joining part is another fastening part, or the joining part is joined to the abutment part through another joining part, or the joining part moves to control the movement or fastening of the another fastening part, or the abutment part drives the joining part to move to control the movement or fastening of the another fastening part, or the joining part first penetrates through the body and is then joined to the abutment part through the another joining part, or the joining part first penetrates through the body and the elastic component and is then joined to the abutment part through the another joining part.

In the abutment structure, the abutment part is provided with a limiting part and a releasing part for rotationally restricting a restricted position of the fastening part or restricting a released position of the fastening part, or where the elastic component is a torsion spring or a torsional elastic body for driving the abutment part to remain normally at a position of restricting the fastening part or remain normally a position of releasing the fastening part, or where the fastening part is a spherical body, an inclined surface body, a one-way inclined surface body, a cylindrical body or a fastening body, or where two ends of the elastic component are respectively limited by the body and the abutment part, or the body or the abutment part is provided with a restricting part for restricting a rotation angle of the abutment part, or where the limiting part or the releasing part is an arc surface, an inclined surface, a spherical surface, a groove, a hole, a flat surface, a recess or a protrusion.

In the abutment structure, the body is provided with an arrangement part for allowing the fastening part to reach an arrangement position through the arrangement part.

In the abutment structure, the abutment part abuts against the fastening part, the body is provided with an arrangement part, a limiting part, and a lifting part, the limiting part restricts the abutment part, the abutment part moves longitudinally to allow the fastening part to reach an arrangement position of the arrangement part, and the lifting part is configured to rest against the rotated abutment part.

In the abutment structure, the abutment structure further includes an elastic component, the abutment part abuts against the fastening part, the body is provided with a limiting part, and the abutment part moves longitudinally or rotationally to allow the elastic component to be elastically limited by or elastically separated from the limiting part, or the abutment part drives the fastening part to reach an arrangement position, or the abutment part is provided with a releasing part, or is configured to rotationally restrict a restricted position or a released position of the fastening part through the releasing part.

In the abutment structure, the abutment part abuts against the fastening part, the body, the abutment part and the elastic component are integrally formed, the body is provided with an arrangement part and a limiting part, the abutment part moves longitudinally or rotationally to allow the elastic component to be elastically limited by or elastically separated from the limiting part, causing the abutment part to drive the fastening part to reach an arrangement position of the arrangement part, the abutment part is provided with a releasing part, and the releasing part is configured to rotationally restrict a restricted position of the fastening part or restrict a released position of the fastening part, so that the fastening part achieves the required position restriction or position release under the cooperation with the releasing part.

In the abutment structure, the body is provided with an arrangement part for allowing the fastening part to reach an arrangement position through the arrangement part and then allowing the abutment part to abut against the fastening part, or the arrangement position is a position opposite to the arrangement part or a position that is reachable by free fall, or the arrangement position is a position that is reachable by the fastening part through the arrangement part by free fall.

In the abutment structure, the abutment structure further includes another fastening part, the body is provided with an arrangement part for allowing the fastening part to pass through and reach an arrangement position, and the abutment part is joined to the another fastening part through a joining part, so that the abutment part moves to control the movement or fastening of the fastening part.

In the abutment structure, the body is provided with an arrangement part for allowing the fastening part to reach an arrangement position through the arrangement part, or the abutment part configured to be joined to another fastening part through a joining part, or the abutment part moves to control or drive the movement or fastening of the fastening part, or the body is provided with an arrangement part for allowing the fastening part to reach an arrangement position through the arrangement part and allowing the abutment part to be arranged on the body or penetrate through the body to abut against the fastening part.

In the abutment structure, the body is provided with a rotating part, or the abutment part is provided with a corresponding rotating part, or the abutment part is rotated to allow the rotating part to cooperate with the corresponding rotating part, or the abutment part or another fastening part spirally controls the movement of the fastening part.

In the abutment structure, the abutment structure further includes another fastening part, the another fastening part abuts against the fastening part, the body is provided with a rotating part, the abutment part is provided with a corresponding rotating part, and the abutment part is rotated to allow the rotating part to cooperate with the corresponding rotating part, enabling the another fastening part to spirally control the movement of the fastening part.

In the abutment structure, the body, the abutment part, and the elastic component are integrally formed, and the elastic component is elastically deformable and fastened to the limiting part of the body, so as to limit the abutment part or prevent the corresponding rotating part of the abutment part from being separated or releasing from the rotating part.

In the abutment structure, the body is provided with a handle part, the body is arranged on an object, and the fastening part is fastened to another object, or the fastening part is a spherical body, an outer fastening body, a threaded body, a cylindrical body, an elastic fastening body, an inner fastening body, an inclined surface body or a curved surface body, or where the object or the another object is connected to a heat sink, or the heat sink provides heat dissipation for a heating element, or where the object or the another object is a main board, a metal body, a plastic body, a server, a transistor, a connector, a rail, a rack, a cabinet, a liquid cooled pipe or a liquid cooled joint.

In the abutment structure above, the body is provided with an arrangement part for allowing the fastening part to enter or reach an arrangement position or a fastening position, the arrangement part is located at a position on a side of, above or below the body, or the fastening part is enabled to enter the body through the arrangement part for the abutment part to abut against the fastening part or for the abutment part to switch the fastening part, or the body is assembled with an elastic component to abut against the abutment part, or the body is assembled with an elastic component to abut against the body and the abutment part, or the abutment part is provided with a guiding part for guiding the fastening part to move, or the guiding part is an inclined surface, a curved surface, an arc surface, a stepped part, a recess, a protrusion or a flat surface, or the abutment part is provided with a limiting part for limiting a position of the fastening part or a position after movement, or where the number of the fastening parts is one, two or more, or where the fastening part reaches the arrangement position through the arrangement part by free fall.

In the abutment structure, the fastening part is an outer fastening body, a threaded body, a cylindrical body, an elastic fastening body, an inner fastening body, an inclined surface body or a curved surface body.

In the abutment structure, the body is provided with at least one fastening part, and the body is laterally connected to an object through the fastening part.

In the abutment structure above, the body is provided with an arrangement part for allowing the fastening part to enter or reach an arrangement position or a fastening position, or the arrangement part is located at a position on a side of, above or below the body, or the fastening part is first enabled to enter the body through the arrangement part, or the fastening part enters an arrangement position or a fastening position for the abutment part to abut against the fastening part or for the abutment part to switch the fastening part, or the body is assembled with an elastic component to abut against the abutment part, or the body is assembled with an elastic component to abut against the body and the abutment part, or the abutment part is provided with a guiding part for guiding the fastening part to move, or the guiding part is an inclined surface, a curved surface, an arc surface, a stepped part, a recess, a protrusion or a flat surface, or the abutment part is provided with a limiting part for limiting a position of the fastening part or a position after movement, or where the number of the fastening parts is one, two or more, or where the fastening part reaches the arrangement position through the arrangement part by free fall.

In the abutment structure, the body is provided with an arrangement part for allowing the fastening part to enter or reach an arrangement position or a fastening position, or the arrangement part is located at a position on a side of, above or below the body, or the fastening part is first enabled to enter the body through the arrangement part, or the fastening part enters an arrangement position or a fastening position for the abutment part to abut against the fastening part or for the abutment part to switch the fastening part, or then the body is assembled with an elastic component to abut against the abutment part, or the body is assembled with an elastic component to abut against the body and the abutment part, or the abutment part is provided with a guiding part for guiding the fastening part to move, or the guiding part is an inclined surface, a curved surface, an arc surface, a stepped part, a recess, a protrusion or a flat surface, or the abutment part is provided with a limiting part for limiting a position of the fastening part or a position after movement, or where the number of the fastening parts is one, two or more.

In the abutment structure, the number of the fastening parts is one, two or more.

In the abutment structure, the body is provided with an arrangement part for allowing the fastening part to enter or reach an arrangement position or a fastening position, or the arrangement part is located at a position on a side of, above or below the body, or the fastening part is first enabled to enter the body through the arrangement part, or the fastening part enters an arrangement position or a fastening position for the abutment part to abut against the fastening part or for the abutment part to switch the fastening part, or then the body is assembled with an elastic component to abut against the abutment part, or the body is assembled with an elastic component to abut against the body and the abutment part, or the abutment part is provided with a guiding part for guiding the fastening part to move, or the guiding part is an inclined surface, a curved surface, an arc surface, a stepped part, a recess, a protrusion or a flat surface, or the abutment part is provided with a limiting part for limiting a position of the fastening part or a position after movement, or where the number of the fastening parts is one, two or more.

In the abutment structure, the body is provided with an arrangement position for arranging the fastening part, or the arrangement position is located at a position on a side of, above or below the body, or the fastening part enters an arrangement position or a fastening position for the abutment part to abut against the fastening part or the abutment part to switch the fastening part, or then the body is provided with an elastic component to abut against the abutment part, or the body is provided with an elastic component to abut against the body and the abutment part, or the abutment part is provided with a guiding part for guiding the fastening part to move, or the guiding part is an inclined surface, a curved surface, an arc surface, a stepped part, a recess, a protrusion or a flat surface, or the abutment part is provided with a limiting part for limiting a position of the fastening part or a position after movement, or where the number of the fastening parts is one, two or more.

In the abutment structure, the body is provided with an anti-rotating part for preventing an object from rotating, or the abutment part is provided with another anti-rotating part for preventing the body from rotating, or the another anti-rotating part is configured to restrict a position or actuation of the abutment part, or the another anti-rotating part is configured to restrict a fastening direction, a fastening angle or a fastening position of the fastening part.

In the abutment structure, the body is provided with an arrangement part for assembling or placing the fastening part, the body is provided with an arrangement position, and the arrangement position is a position opposite to the arrangement part or a position that is reachable by free fall, or the arrangement position is a position that is reachable by the fastening part through the arrangement part by free fall.

In the abutment structure, the elastic component is a torsion spring, with two ends of the torsion spring respectively arranged on the body and the abutment part, to allow the abutment part to rotate elastically to abut against the fastening part, and enable the fastening part to be located at a fastening position or a non-fastening position, or where the body or the abutment part is provided with a limiting part for limiting the abutment part, to enable the fastening part to be located at a fastening position or a non-fastening position, or where the abutment structure further includes an elastic component, and the elastic component is arranged between the body and the abutment part and located on an inner side or an outer side of the body, or where the body, the abutment part and the elastic component are integrally formed, or the elastic component is elastically deformable and fastened to a limiting part of the body to limit the abutment part or prevent a corresponding rotating part of the abutment part from being separated or loosened from the rotating part, or where the abutment structure is connected with a heat sink, or the heat sink provides heat dissipation for a heating element, or where the abutment structure is connected to a main board, a metal body, a plastic body, a server, a transistor, a connector, a rail, a rack, a cabinet, a liquid cooled pipe or a liquid cooled joint.

In the abutment structure, the body is provided with an anti-rotating part, and the anti-rotating part is configured to limit a direction of the body, or the anti-rotating part is configured to limit a fastening direction of the abutment part, or the anti-rotating part is configured to limit directions of the body, the abutment part and the object.

In the abutment structure, the abutment structure is provided with an elastic component, or the elastic component is arranged between the body and the abutment part and located on an inner side or an outer side of the body, or where the body or the abutment part and the elastic component are integrally formed, or the elastic component is elastically deformable and fastened to a limiting part of the body to limit the abutment part.

In the abutment structure, the body is provided with an arrangement part, and an object enters the body through the arrangement part and is fastened, interfered, limited, locked or conducted by the abutment part, or where the object is a fastened body, a conductive body, a line, a fastening body, a spherical body, a rod body, an optical fiber, a cylindrical body or a plate body, or the abutment part is a fastening part, a cylindrical body, a threaded body, a protrusion body, a rod body, a recess body or a flat surface body, or two ends of the elastic component respectively abut against the body and the abutment part, or the arrangement part is a hole, a groove, a trench or a space.

In the abutment structure, the body is provided with an arrangement part, and an object enters the body through the arrangement part and is fastened, interfered, limited, locked or conducted by the abutment part, or where the object is a fastened body, a conductive body, a line, a fastening body, a spherical body, a rod body, an optical fiber, a cylindrical body or a plate body, or the abutment part is a fastening part, a cylindrical body, a threaded body, a protrusion body, a rod body, a recess body or a flat surface body, or the arrangement part is a hole, a groove, a trench or a space.

In the abutment structure, the abutment structure further includes an elastic component, and the elastic component is arranged between the body and the abutment part and located on an inner side or an outer side of the body.

In the abutment structure, the abutment part is a toggle member, printed circuit board, case, integrated circuit, metal member or plastic member, the body is a handle, and the abutment part is joined to another fastening part through another joining part, and is configured to toggle the abutment part to control the another fastening part to be fastened to or unfastened from another object.

In the abutment structure, the body is provided with an accommodating part, and the accommodating part is configured to accommodate the abutment part to reduce the height of the abutment part, or the abutment part is raised and then rotationally arranged at a high position of the body outside the accommodating part to allow the abutment part to move to switch the fastening part.

Optionally, the number of the abutment parts is two, and the abutment parts abut against each other, or one abutment part is connected to the body through a joining part, or one abutment part rotates or moves to switch the fastening part.

Optionally, the abutment part is moved to undergo elastic movement with the elastic component, so that the fastening part reaches an accommodating position of the abutment part from an abutment position of the abutment part, enabling the fastening part to move.

Optionally, the abutment structure is connected to a heat sink, and the heat sink is used for dissipating heat from a heating element.

Optionally, the abutment structure is configured to connect at least two objects, and a gap space is reserved between the two objects, or the two objects are in close fit, or the two objects are respectively a circuit board, a metal object or a plastic plate, or the two objects are both metal objects, circuit boards or plastic plates, or the body is provided with a shoulder, and the gap space is formed between the two objects through the shoulder.

Optionally, the abutment structure may be provided with a moving part, or the moving part is provided with a movement limiting part or a channel, the movement limiting part is communicated with the channel, the moving part moves laterally, the abutment part is enabled to lift from a low position of the movement limiting part to a high position of the channel, and the abutment part is enabled to move to switch the fastening part.

Optionally, the abutment structure is provided with a moving part, the body is provided with an anti-rotating part, the moving part is provided with another corresponding anti-rotating part, and the anti-rotating part cooperates with the another corresponding anti-rotating part to restrict a rotation position or an actuation direction of the moving part.

Optionally, the abutment structure is arranged on a heat sink to fasten an object through the fastening part, where the object is provided with a heating element, and the heat sink provides heat dissipation for the heating element, or where the object is a printed circuit board, or the heating element is a chip, or the object or the heating element is a conductive body; or the abutment structure is arranged on an object to fasten a heat sink through the fastening part, where the object is provided with a heating element, and the heat sink provides heat dissipation for the heating element, or where the object is a printed circuit board, or the heating element is a chip, or the object or the heating element is a conductive body.

Optionally, the body is provided with an arrangement part and an arrangement position, and the arrangement part is larger than the arrangement position to allow the fastening part to reach the arrangement position through the arrangement part and then be limited.

Optionally, the body is provided with an arrangement part and an arrangement position, the arrangement part is larger than the arrangement position to allow the fastening part to reach the arrangement position through the arrangement part, and the abutment part is configured to abut against the fastening part, or the abutment part is configured to control or drive the movement or fastening of the fastening part, or the arrangement part is a hole, a groove, a trench or a space.

Optionally, the body has two arrangement parts, two fastening parts, and two arrangement positions to allow the two fastening parts to reach the two arrangement positions through the two arrangement parts.

Optionally, the body has a connecting part configured to be riveted, flared, welded, or locked to an object, or the connecting part is integrally formed with the object, or the object is a printed circuit board, a metal member, a plastic member or a heat sink.

Optionally, the body has a connecting part configured to be welded to the object through solder, where the object is a printed circuit board or a chip.

The present disclosure provides an abutment method of an abutment structure. The abutment structure includes a body, at least one abutment part, and an elastic component, where the abutment part is movably arranged on the body, and the elastic component is arranged between the body and the abutment part, and forms an elastic pressing space between the body and the abutment part in use.

The present disclosure provides another abutment method of an abutment structure. The abutment structure includes a body, at least one abutment part, an elastic component, and another fastening part, the body is provided with an arrangement part for allowing the another fastening part to pass through and reach an arrangement position to combine a joining part with the body, or the joining part is another fastening part, or the joining part is the abutment part for abutting against the another fastening part, or the joining part is joined to the abutment part through another joining part, or the another joining part moves to control the movement or fastening of the another fastening part, or the abutment part drives the another joining part to control the movement or fastening of the another fastening part, or where the another fastening part is a spherical body, an inclined surface body, a one-way inclined surface body, a cylindrical body or a fastening body, or the arrangement part or the arrangement position is a through hole, a movement space or groove, an inclined surface part, a stepped part, an arc surface part, a right-angled part or a non-right-angled part.

The present disclosure provides another abutment method of an abutment structure. The abutment structure includes a body, and at least one abutment part, or an elastic component, or a fastening part, or the body is provided with an arrangement part, or to allow the fastening part to pass through and reach an arrangement position, or allow a joining part to be joined to the body, or the joining part is another fastening part, or the joining part is the abutment part for abutting against the fastening part, or the joining part is joined to the abutment part through another joining part, or the another joining part moves to control the movement or fastening of the fastening part, or the abutment part drives the another joining part to move to control the movement or fastening of the fastening part, or where the fastening part or the another fastening part is a spherical body, an inclined surface body, a one-way inclined surface body, a cylindrical body or a fastening body, or the arrangement part or the arrangement position is a through hole, a movement space or groove, an inclined surface part, a stepped part, an arc surface part, a right-Angled part or a non-right-angled part.

The present disclosure provides another abutment method of an abutment structure. The abutment structure includes a body, at least one abutment part, and an elastic component, where the abutment structure further includes a joining part configured to be joined to the body, or the joining part is another fastening part, or the joining part is joined to the abutment part through another joining part, or the joining part moves to control the movement or fastening of the another fastening part, or the abutment part drives the joining part to move to control the movement or fastening of the another fastening part, or the joining part first penetrates through the body and is then joined to the abutment part through the another joining part, or the joining part first penetrates through the body and the elastic component and is then joined to the abutment part through the another joining part.

The present disclosure provides another abutment method of an abutment structure. The abutment structure includes a body, at least one abutment part, and an elastic component, where the abutment part is provided with a limiting part and a releasing part for rotationally restricting a restricted position of the fastening part or restricting a released position of the fastening part, or where the elastic component is a torsion spring or a torsional elastic body for driving the abutment part to remain normally at a position of restricting the fastening part or remain normally a position of releasing the fastening part, or where the fastening part is a spherical body, an inclined surface body, a one-way inclined surface body, a cylindrical body or a fastening body, or where two ends of the elastic component are respectively limited by the body and the abutment part, or the body or the abutment part is provided with a restricting part for restricting a rotation angle of the abutment part, or where the limiting part or the releasing part is an arc surface, an inclined surface, a spherical surface, a groove, a hole, a flat surface, a recess or a protrusion.

The present disclosure provides another abutment method of an abutment structure. The abutment structure includes a body, at least one abutment part, and an elastic component, where the body is provided with an arrangement part to allow the fastening part to pass through and reach an arrangement position, or further allow the abutment part to be assembled on or penetrate through the body, or allowing the abutment part to control the fastening part, or the body is provided with an arrangement part to allow the fastening part to reach an arrangement position through the arrangement part, then allowing the abutment part to be arranged on the body or penetrate through the body to abut against the fastening part.

The present disclosure provides another abutment method of an abutment structure. The abutment structure includes a body, at least one abutment part, and an elastic component, where the body is provided with an arrangement part to allow the fastening part to pass through and reach an arrangement position, or configured to be joined to the body through a joining part, or the joining part is the abutment part for abutting against the fastening part, or the abutment part is configured to abut against the fastening part, or the abutment part moves to control the movement or fastening of the fastening part, or the joining part is joined to the abutment part through another joining part, or the another joining part moves to control the movement or fastening of the fastening part, or the abutment part drives the another joining part to move to control the movement or fastening of the fastening part, or where the fastening part is a spherical body, an inclined surface body, a one-way inclined surface body, a cylindrical body or a fastening body, or the arrangement part is a through hole, a movement space or groove, an inclined surface part, a stepped part, an arc surface part, a right-angled part or a non-right-angled part, or the abutment part is another fastening part, or the joining part is another fastening part, or the abutment part is the fastening part, or the joining part is the fastening part, or where the abutment part and the joining part are integrally formed, or where the abutment part and the joining part are connected to each other, or where the abutment part is a joining part, or where the fastening part reaches the arrangement position through the arrangement part by free fall, or where the fastening part reaches the arrangement position under the help of a tool or a magnetic tool, or where the fastening part reaches the arrangement position through the arrangement part under the help of a tool or a magnetic tool.

### BRIEF DESCRIPTION OF THE DRAWINGS

FIG. 1 is a schematic diagram I according to a first embodiment of the present disclosure.

FIG. 2 is a schematic diagram II according to a first embodiment of the present disclosure.

FIG. 3 is a schematic diagram according to a second embodiment of the present disclosure.

FIG. 4 is a schematic diagram I according to a forty-third embodiment of the present disclosure.

FIG. 5 is a schematic diagram II according to a forty-third embodiment of the present disclosure.

FIG. 6 is a schematic diagram according to a fourth embodiment of the present disclosure.

FIG. 7 is a schematic diagram I according to a fifth embodiment of the present disclosure.

FIG. 8 is a schematic diagram II according to a fifth embodiment of the present disclosure.

FIG. 9 is a schematic diagram according to a sixth embodiment of the present disclosure.

FIG. 10 is a schematic diagram according to a seventh embodiment of the present disclosure.

FIG. 11 is a schematic diagram according to an eighth embodiment of the present disclosure.

FIG. 12 is a schematic diagram according to a ninth embodiment of the present disclosure.

FIG. 13 is a schematic diagram according to a tenth embodiment of the present disclosure.

FIG. 14 is a schematic diagram according to an eleventh embodiment of the present disclosure.

FIG. 15 is a schematic diagram according to a twelfth embodiment of the present disclosure.

FIG. 16 is a schematic diagram according to a thirteenth embodiment of the present disclosure.

FIG. 17 is a schematic diagram according to a fourteenth embodiment of the present disclosure.

FIG. 18 is a schematic diagram according to a fifteenth embodiment of the present disclosure.

FIG. 19 is a schematic diagram according to a sixteenth embodiment of the present disclosure.

FIG. 20 is a schematic diagram according to a seventeenth embodiment of the present disclosure.

FIG. 21 is a schematic diagram according to an eighteenth embodiment of the present disclosure.

FIG. 22 is a schematic diagram according to a nineteenth embodiment of the present disclosure.

FIG. 23 is a schematic diagram according to a twentieth embodiment of the present disclosure.

FIG. 24 is a schematic diagram according to a twenty-first embodiment of the present disclosure.

FIG. 25 is a schematic diagram according to a twenty-second embodiment of the present disclosure.

FIG. 26 is a schematic diagram I according to a twenty-third embodiment of the present disclosure.

FIG. 27 is a schematic diagram II according to a twenty-third embodiment of the present disclosure.

FIG. 28 is a schematic diagram I according to a twenty-fourth embodiment of the present disclosure.

FIG. 29 is a schematic diagram II according to a twenty-fourth embodiment of the present disclosure.

FIG. 30 is a schematic diagram according to a twenty-fifth embodiment of the present disclosure.

FIG. 31 is a schematic diagram I according to a twenty-sixth embodiment of the present disclosure.

FIG. 32 is a schematic diagram II according to a twenty-sixth embodiment of the present disclosure.

FIG. 33 is a schematic diagram III according to a twenty-sixth embodiment of the present disclosure.

FIG. 34 is a schematic diagram I according to a twenty-seventh embodiment of the present disclosure.

FIG. 35 is a schematic diagram II according to a twenty-seventh embodiment of the present disclosure.

FIG. 36 is a schematic diagram according to a twenty-eighth embodiment of the present disclosure.

FIG. 37 is a schematic diagram I according to a twenty-ninth embodiment of the present disclosure.

FIG. 38 is a schematic diagram II according to a twenty-ninth embodiment of the present disclosure.

FIG. 39 is a schematic diagram according to a thirtieth embodiment of the present disclosure.

FIG. 40 is a schematic diagram according to a thirty-first embodiment of the present disclosure.

FIG. 41 is a schematic diagram according to a thirty-second embodiment of the present disclosure.

FIG. 42 is a schematic diagram according to a thirty-third embodiment of the present disclosure.

FIG. 43 is a schematic diagram according to a thirty-fourth embodiment of the present disclosure.

FIG. 44 is a schematic diagram according to a thirty-fifth embodiment of the present disclosure.

FIG. 45 is a schematic diagram according to a thirty-sixth embodiment of the present disclosure.

### DETAILED DESCRIPTION OF THE INVENTION

A fluid coupling structure according to an embodiment of the present disclosure will be further described below with reference to the drawings.

The above and other technical contents, features, and effects related to the present disclosure will be clearly presented below in the detailed description of the exemplary embodiments with reference to the drawings. It is worth mentioning that the directional language mentioned in the following embodiments, such as up, down, left, right, front or back, are only directions with reference to the drawings. Therefore, the directional language used is intended to describe rather than limit the present disclosure. In addition, in the following embodiments, identical or similar components will be labeled with the same or similar reference signs.

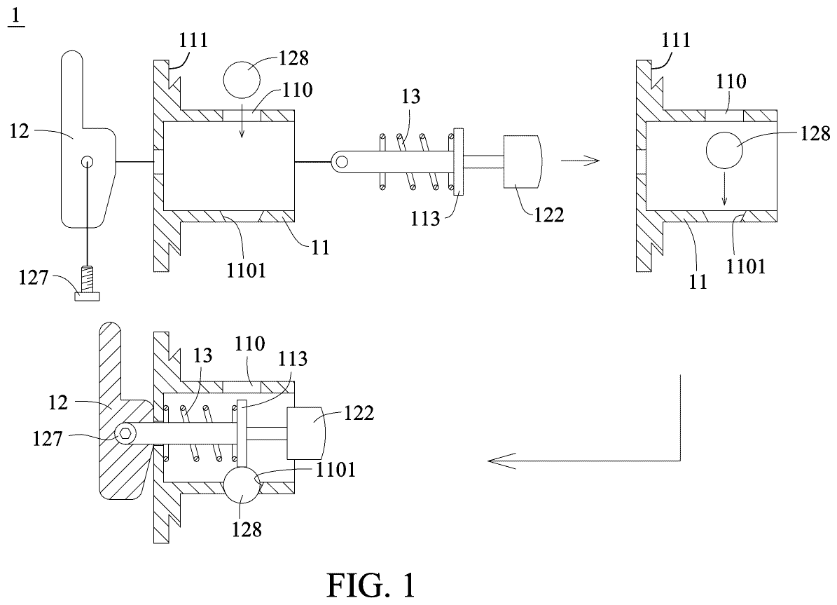

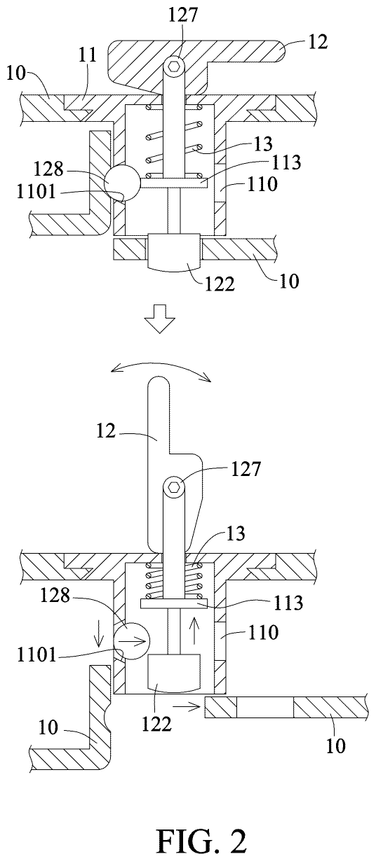

Referring to FIG. 1 and FIG. 2. The present disclosure provides an abutment structure and an abutment method thereof. The abutment structure 1 includes a body 11, at least one abutment part 12, and a fastening part 128.

The abutment part 12 is movably arranged on the body 11.

The abutment part 12 abuts against the fastening part 128 (or the abutment part 12 is configured to control or drive the movement or fastening of the fastening part 128).

In addition to the above embodiment, in an embodiment of the present disclosure, the difference from the above embodiment lies in that the abutment structure further includes an elastic component 13, and the elastic component 13 is arranged between the body 11 and the abutment part 12 and may be located on an inner side or an outer side of the body 11.

In addition to the above embodiment, in an embodiment of the present disclosure, the difference from the above embodiment lies in that one end of the body 11 is provided with a connecting part 111, and the body 11 or the connecting part 111 of the body 11 is configured to be welded, riveted, flared, fastened, or locked to or integrally formed with an object (10). In this way, the present disclosure can better meet the actual application requirements.

In addition to the above embodiment, in an embodiment of the present disclosure, the difference from the above embodiment lies in that the body 11 is provided an arrangement part 110 for allowing the fastening part 128 to pass through and reach an arrangement position 1101 to combine a joining part 113 with the body 11. In this way, the present disclosure can better meet the actual application requirements.

In addition to the above embodiment, in an embodiment of the present disclosure, the difference from the above embodiment lies in that it further allows the abutment part 12 to be assembled on or penetrate through the body 11 or allows the abutment part 12 to control the fastening part 128, and the joining part 113 is another fastening part, or the joining part 113 is the abutment part for abutting against the fastening part 128, or the abutment part 12 is configured to abut against the fastening part 125, or the abutment part 12 moves to control (or drive) the movement or fastening of the fastening part 128. In this way, the present disclosure can better meet the actual application requirements.

In addition to the above embodiment, in an embodiment of the present disclosure, the difference from the above embodiment lies in that the body 11 is provided with an arrangement part 110 for allowing the fastening part 128 to reach an arrangement position through the arrangement part 110, and then allowing the abutment part 12 to be arranged on the body 11 or penetrate through the body 11 to abut against the fastening part 128. In this way, the present disclosure can better meet the actual application requirements.

In addition to the above embodiment, in an embodiment of the present disclosure, the difference from the above embodiment lies in that the joining part 113 is joined to the abutment part 12 through another joining part 127, so that the another joining part 127 moves to control (or drive) the movement or fastening of the fastening part 128 and the abutment part 12 drives the another joining part 127 to move to control (or drive) the movement or fastening of the fastening part 128, where the fastening part 128 may be a spherical body, an inclined surface body, a one-way inclined surface body, a cylindrical body or a fastening body, and the arrangement part 110 may be a through hole, a movement space or groove, an inclined surface part, a stepped part, an arc surface part, a right-angled part or a non-right-angled part. In this way, the present disclosure can better meet the actual application requirements.

In addition to the above embodiment, in an embodiment of the present disclosure, the difference from the above embodiment lies in that the joining part 113 may be joined to the body 11, the joining part 113 is joined to the abutment part 12 through the another joining part 127, so that the joining part 113 moves to control the movement or fastening of another fastening part 122 (or the abutment part 12 drives the joining part 113 to move to control the movement or fastening of the another fastening part 122), and the joining part 113 first penetrates through the body 11 and is then joined to the abutment part 12 through the another joining part 127 (or the joining part 113 first penetrates through the body 11 and the elastic component 13 and is then joined to the abutment part 12 through the another joining part 127. In this way, the present disclosure can better meet the actual application requirements.

In addition to the above embodiment, in an embodiment of the present disclosure, the difference from the above embodiment lies in that the abutment part 12 and the joining part 113 are connected to each other (or the abutment part is a joining part), and the another fastening part 122 reaches the arrangement position 1101 through the arrangement part 110 by free fall, or the another fastening part 122 reaches the arrangement position 1101 under the help of a tool or a magnetic tool. In this way, the present disclosure can better meet the actual application requirements.

In addition to the above embodiment, in an embodiment of the present disclosure, the difference from the above embodiment lies in that the fastening part reaches the arrangement position 1101 through the arrangement part 110 under the help of a tool or a magnetic tool. In this way, the present disclosure can better meet the actual application requirements.

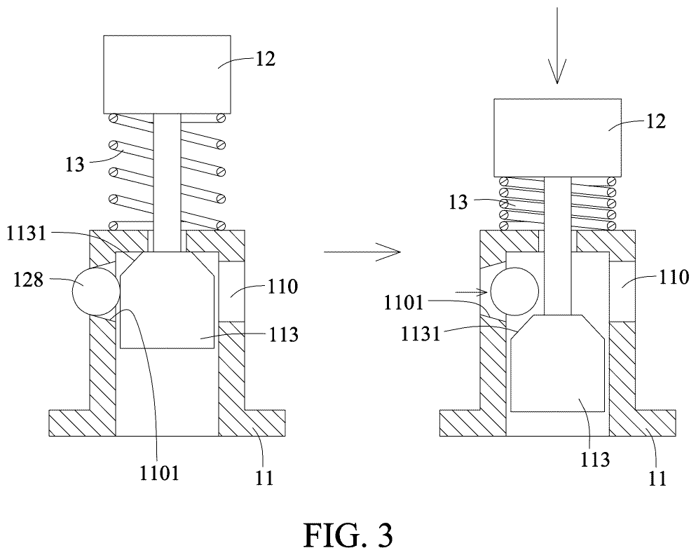

Referring to FIG. 3. In addition to the above embodiment, in an embodiment of the present disclosure, the difference from the above embodiment lies in that the joining part 113 is another fastening part, the abutment part 12 and the joining part 113 are integrally formed, and the joining part 113 abuts against the fastening part 128 through an inclined surface part 1131. In this way, the abutment part 12 can move to control the movement or fastening of the fastening part 128 through the joining part 113, and the present disclosure can better meet the actual application requirements.

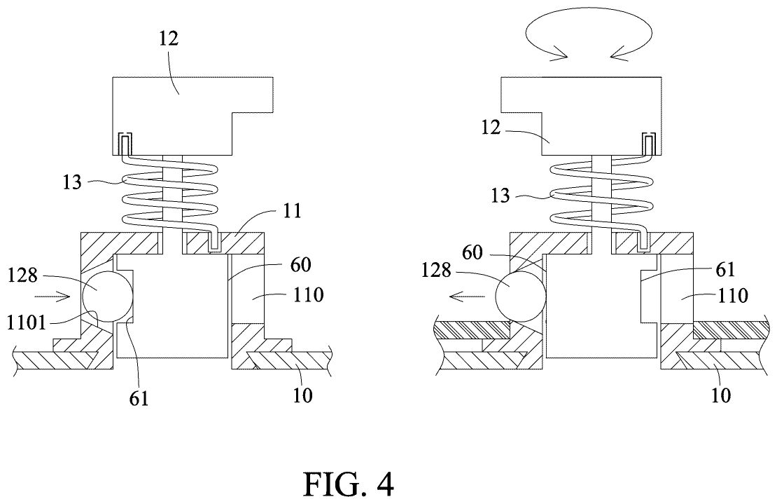

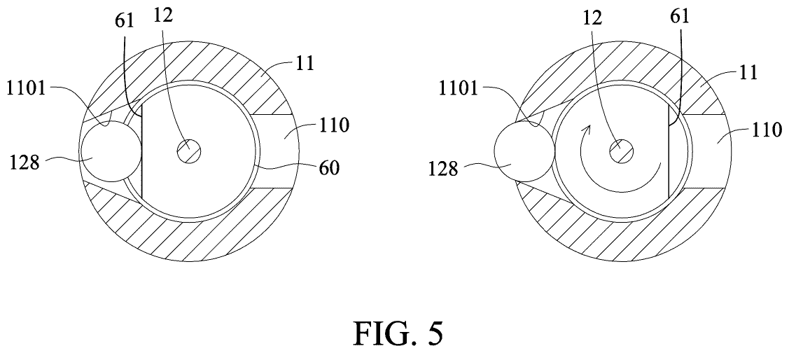

Referring to FIG. 4 and FIG. 5. In addition to the above embodiment, in an embodiment of the present disclosure, the difference from the above embodiment lies in that the abutment structure further includes a fastening part 128, where the fastening part 128 may be a spherical body, an inclined surface body, a one-way inclined surface body, a cylindrical body or a fastening body, the abutment part 12 is provided with a limiting part 60 and a releasing part 61, and the limiting part 60 and the releasing part 61 may be respectively an arc surface, an inclined surface, a spherical surface, a groove, a hole, a flat surface, a recess or a protrusion; the limiting part 60 and the releasing part 61 are configured to rotationally restrict a restricted position of the fastening part 128 or restrict a released position of the fastening part 128. In this way, the fastening part 128 can achieve the required position limitation or position release under the cooperation with the limiting part 60 and the releasing part 61, and the abutment part 12 in the present disclosure can better meet the actual application requirements.

In addition to the above embodiment, in an embodiment of the present disclosure, the difference from the above embodiment lies in that the elastic component 13 is a torsion spring (or torsional elastic body), and two ends of the elastic component 13 are respectively limited by the body 11 and the abutment part 12, so that the elastic component 13 drives the abutment part 12 to remain normally at a position of restricting the fastening part 128 or makes the abutment part 12 normally remain at a position of releasing the fastening part 128. In this way, the present disclosure can better meet the actual application requirements.

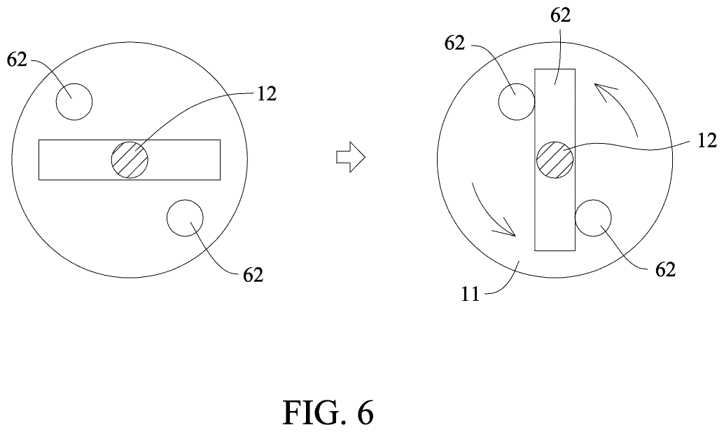

Referring to FIG. 6. In addition to the above embodiment, in an embodiment of the present disclosure, the difference from the above embodiment lies in that the body 11 and the abutment part 12 may be respectively provided with a restricting part 62, and the restricting part 62 is configured to restrict a rotation angle of the abutment part 12. In this way, the present disclosure can better meet the actual application requirements.

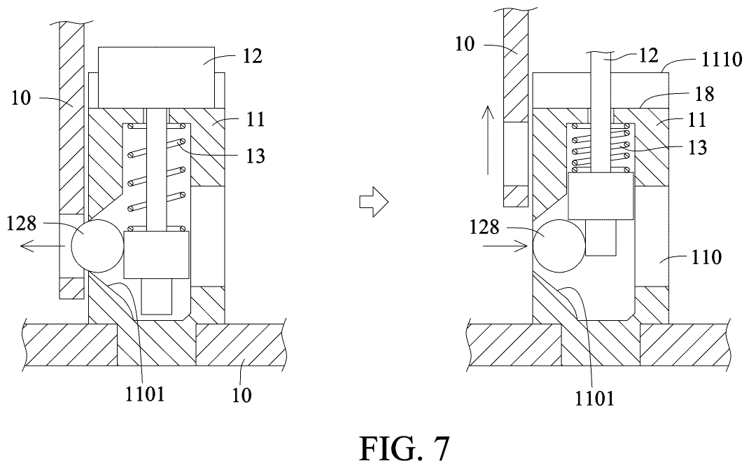

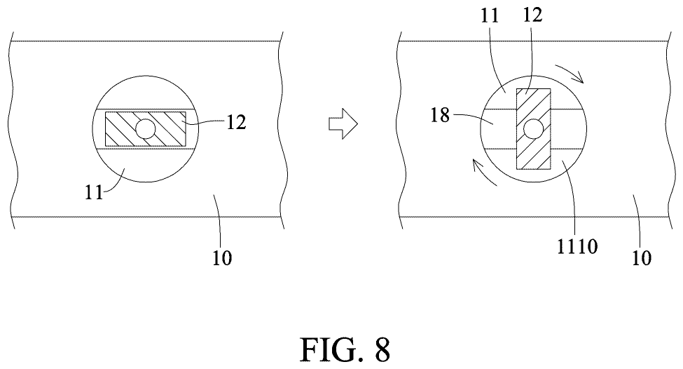

Referring to FIG. 7 and FIG. 8. In addition to the above embodiment, in an embodiment of the present disclosure, the difference from the above embodiment lies in that the abutment structure further includes a fastening part 128, the abutment part 12 abuts against the fastening part 128, the body 11 is provided with an arrangement part 110, a limiting part 60, and a lifting part 1110, the limiting part 60 restricts the abutment part 12, the abutment part 12 moves longitudinally to allow the fastening part 128 to reach an arrangement position 1101 of the arrangement part 110, and the lifting part 1110 is configured to rest against the rotated abutment part 12. In this way, the abutment part 12 can move to control the fastening or unfastening between the fastening part 128 and the object 10, and the present disclosure can better meet the actual application requirements.

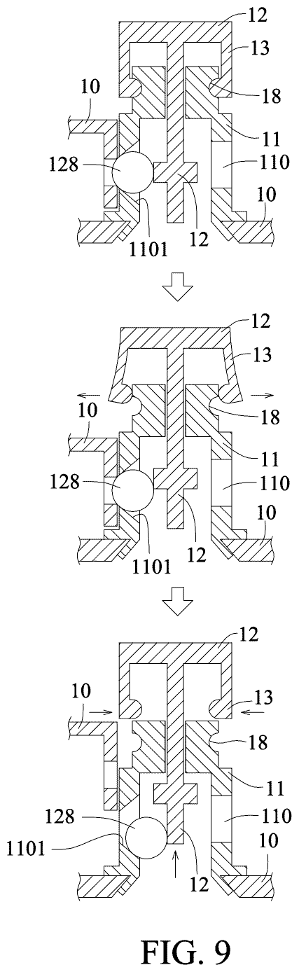

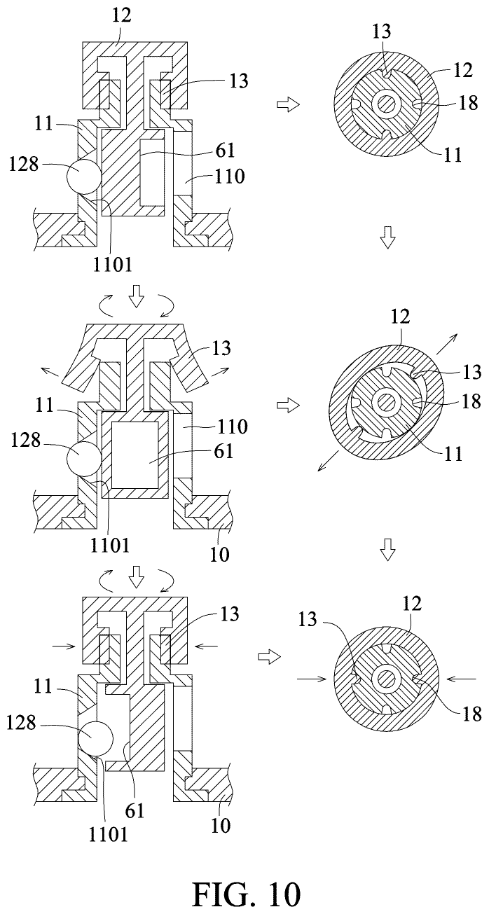

Referring to FIG. 9 and FIG. 10. In addition to the above embodiment, in an embodiment of the present disclosure, the difference from the above embodiment lies in that the abutment structure further includes a fastening part 128, the abutment part 12 abuts against the fastening part 128, the body 11, the abutment part 12 and the elastic component 13 are integrally formed, the body 11 is provided with an arrangement part 110 and a limiting part 60, the abutment part 12 moves longitudinally or rotationally to allow the elastic component 13 to be elastically limited by or elastically separated from the limiting part 60, the abutment part 12 drives the fastening part 128 to reach an arrangement position 1101 of the arrangement part, the abutment part 12 is provided with a releasing part 61, and the releasing part 61 is configured to rotationally restrict a restricted position of the fastening part 128 or restrict a released position of the fastening part 128, so that the fastening part 128 achieve the required position limitation or position release under the cooperation with the releasing part 61. In this way, the present disclosure can better meet the actual application requirements.

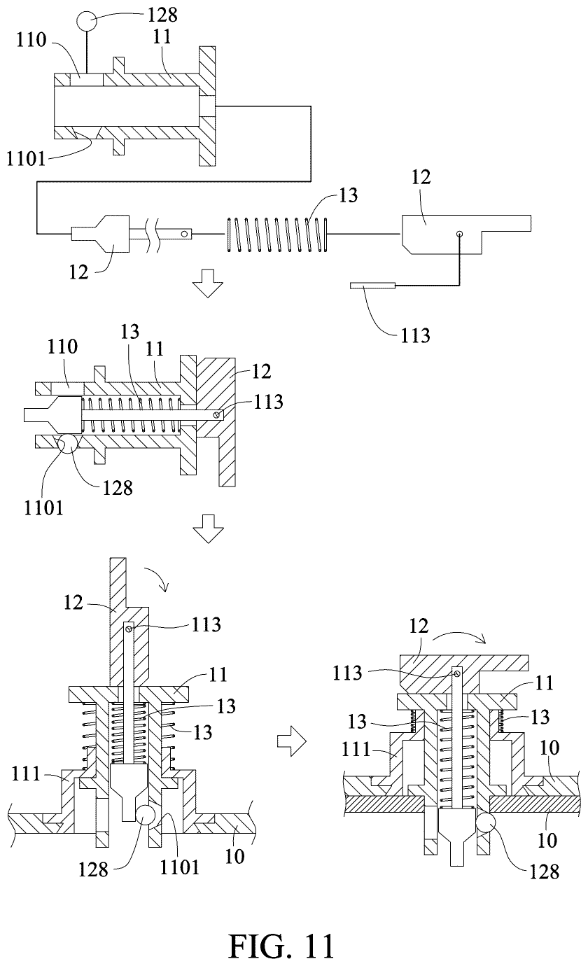

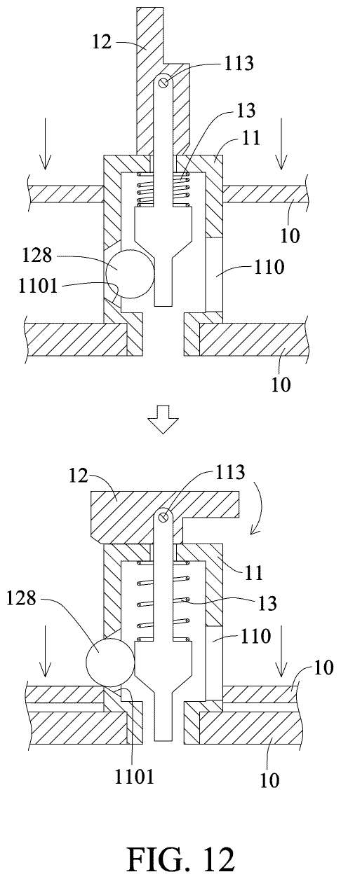

Referring to FIG. 11 and FIG. 12. In addition to the above embodiment, in an embodiment of the present disclosure, the difference from the above embodiment lies in that the abutment structure further includes another fastening part 122 and a fastening part 128, the body 11 is provided with an arrangement part 110 for allowing the fastening part 128 to pass through and reach an arrangement position 1101, and the abutment part 12 is joined to the another fastening part 122 through a joining part 113, so that the abutment part 12 moves to control (or drive) the movement or fastening of the fastening part 128.

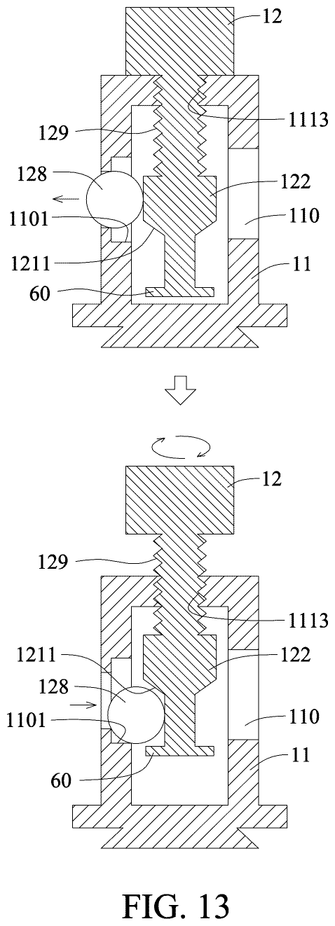

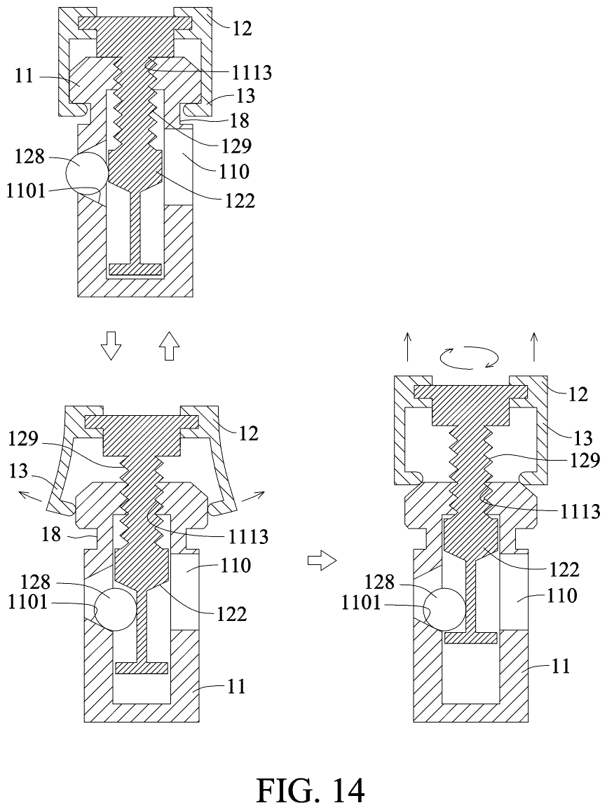

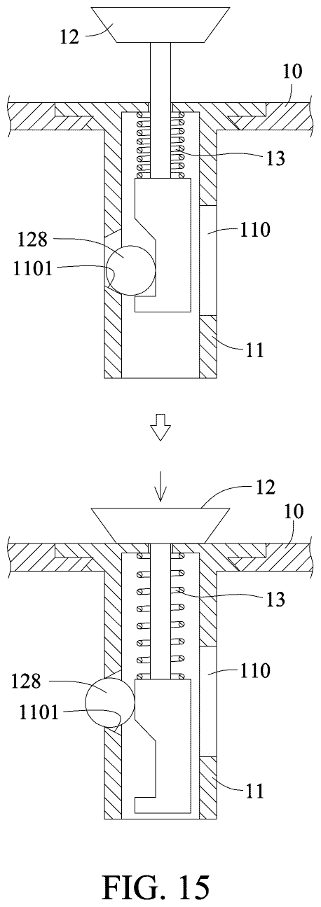

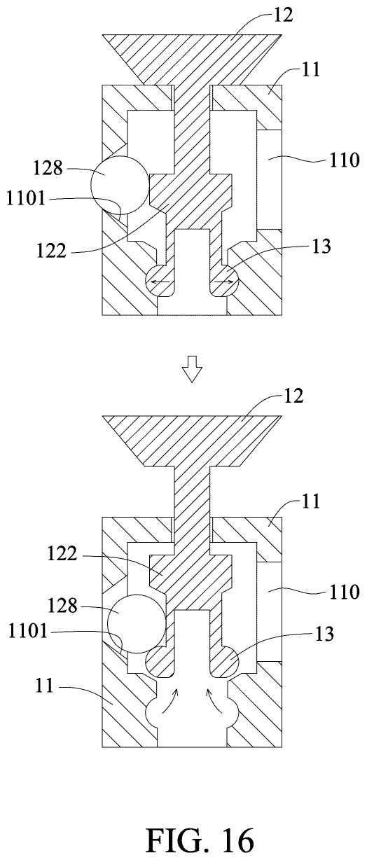

Referring to FIG. 13 to FIG. 16. In addition to the above embodiment, in an embodiment of the present disclosure, the difference from the above embodiment lies in that the abutment structure further includes another fastening part 122 and a fastening part 128, the another fastening part 122 abuts against the fastening part 128, the body 11 is provided with a rotating part 1113, the abutment part 12 is provided with a corresponding rotating part 129, by rotating the abutment part 12, the rotating part 1113 cooperates with the corresponding rotating part 129, so that the another fastening part 122 spirally controls the movement of the fastening part 128. In this way, the present disclosure can better meet the actual application requirements.

In addition to the above embodiment, in an embodiment of the present disclosure, the difference from the above embodiment lies in that the body 11, the abutment part 12, and the elastic component 13 are integrally formed, and the elastic component 13 is elastically deformable and fastened to the limiting part 60 of the body 11, so as to limit the abutment part 12 or prevent the corresponding rotating part 129 of the abutment part 12 from being separated or released from the rotating part 1113. In this way, the present disclosure can better meet the actual application requirements.

In addition to the above embodiment, in an embodiment of the present disclosure, the difference from the above embodiment lies in that the fastening part 128 enters (or reaches) the arrangement position 1101 (or the fastening position) to abut against the fastening part 128 through the abutment part 12 or to switch the fastening part 128 through the abutment part 12. In this way, the abutment part 12 and the fastening part 128 in the present disclosure can better meet the actual application requirements.

In addition to the above embodiment, in an embodiment of the present disclosure, the difference from the above embodiment lies in that the body 11 is assembled with the elastic component 13 which abuts against the abutment part 12, or the body 11 is assembled with the elastic component 13 which abuts against the body 11 and the abutment part 13, so that the abutment part 12 achieves automatic restoration, elastic fastening or positioning after actuation under the cooperation with the elastic component 13.

In addition to the above embodiment, in an embodiment of the present disclosure, the difference from the above embodiment lies in that the abutment part 12 is provided with a guiding part 1211 for guiding the fastening part 128 to move, the guiding part 1211 may be an inclined surface, a curved surface, an arc surface, a stepped part, a recess, a protrusion or a flat surface, and the abutment part 12 is provided with a limiting part 60 for limiting a position of the fastening part 128 or a position after movement. In this way, the abutment part 12 and the fastening part 128 in the present disclosure can better meet the actual application requirements.

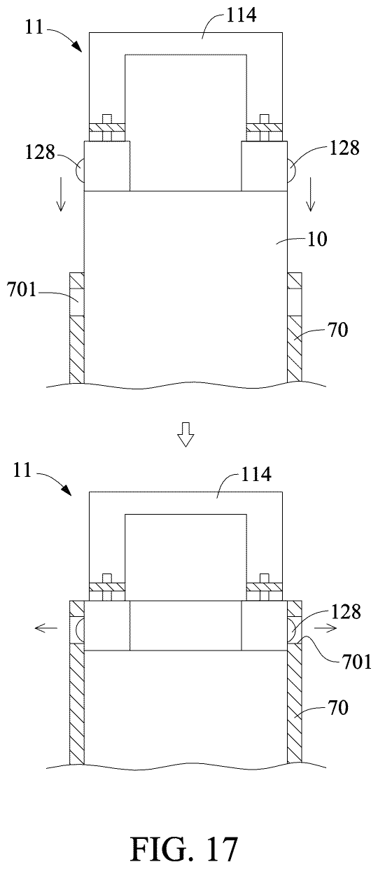

Referring to FIG. 17. In addition to the above embodiment, in an embodiment of the present disclosure, the difference from the above embodiment lies in that the body 11 is provided with a handle part 114 and a fastening part 128, the body 11 is arranged on an object 10, and the fastening part 128 is fastened to a fastened part 701 of another object 70, or the abutment part 12 and the fastening part 128 are respectively fastened to the fastened part 701 of the another object 70. In this way, the present disclosure can better meet the actual application requirements.

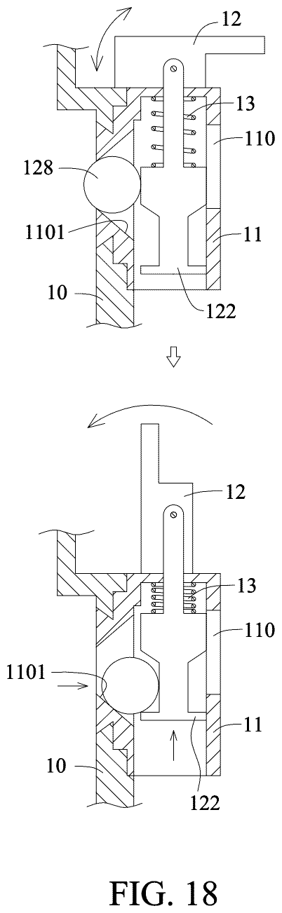

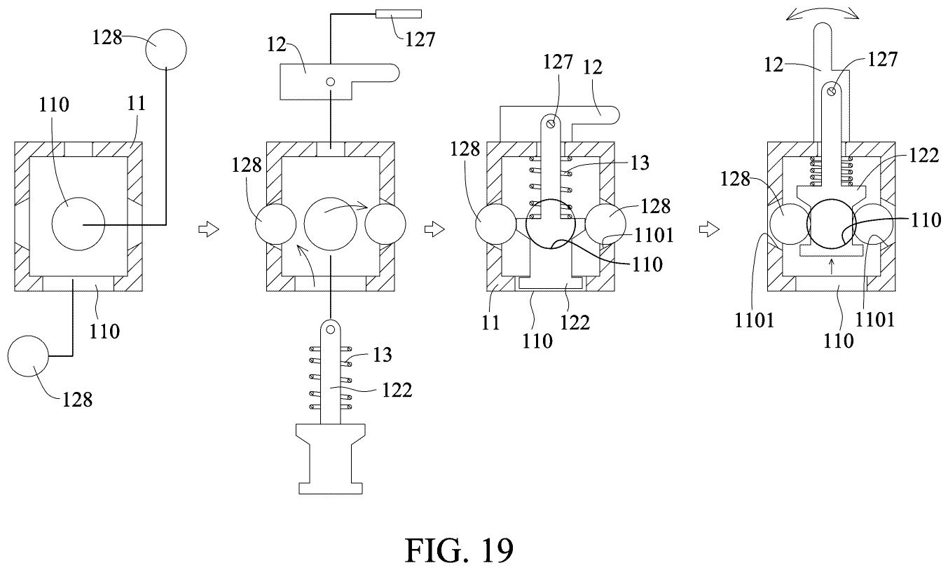

Referring to FIG. 18 and FIG. 19. In addition to the above embodiment, in an embodiment of the present disclosure, the difference from the above embodiment lies in that the body 11 is provided with at least one fastening part 128, and the body 11 is laterally connected to an object 10 through the fastening part 128. In this way, the present disclosure can better meet the actual application requirements.

In addition to the above embodiment, in an embodiment of the present disclosure, the difference from the above embodiment lies in that the body 11 is provided with an arrangement part 110 for allowing the fastening part 128 to enter (or reach) an arrangement position 1101 (or a fastening position), or the arrangement part 110 is located at a position on a side of, above or below the body 11, or the fastening part 128 is first enabled to enter the body 11 through the arrangement part 110, and then the body 11 is assembled with the elastic component 13 at the abutment part 12 and bolted to the another fastening part 122 and the abutment part 12 through the another joining part 127. In this way, the present disclosure can better meet the actual application requirements.

In addition to the above embodiment, in an embodiment of the present disclosure, the difference from the above embodiment lies in that the number of the fastening parts 128 is one, two or more. In this way, the present disclosure can better meet the actual application requirements.

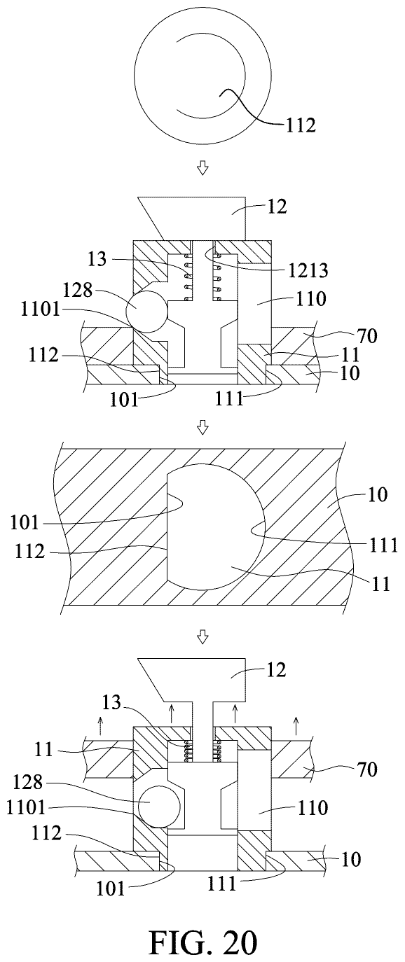

Referring to FIG. 20. In addition to the above embodiment, in an embodiment of the present disclosure, the difference from the above embodiment lies in that the body 11 is provided with an anti-rotating part 112 for preventing the object 10 from rotating, the abutment part 12 is provided with another anti-rotating part 1213 for preventing the body 11 from rotating, or the another anti-rotating part 1213 is configured to restrict a position or actuation of the abutment part 12, or the another anti-rotating part 1213 is configured to restrict a fastening direction, a fastening angle or a fastening position of the fastening part 128. In this way, the present disclosure can better meet the actual application requirements.

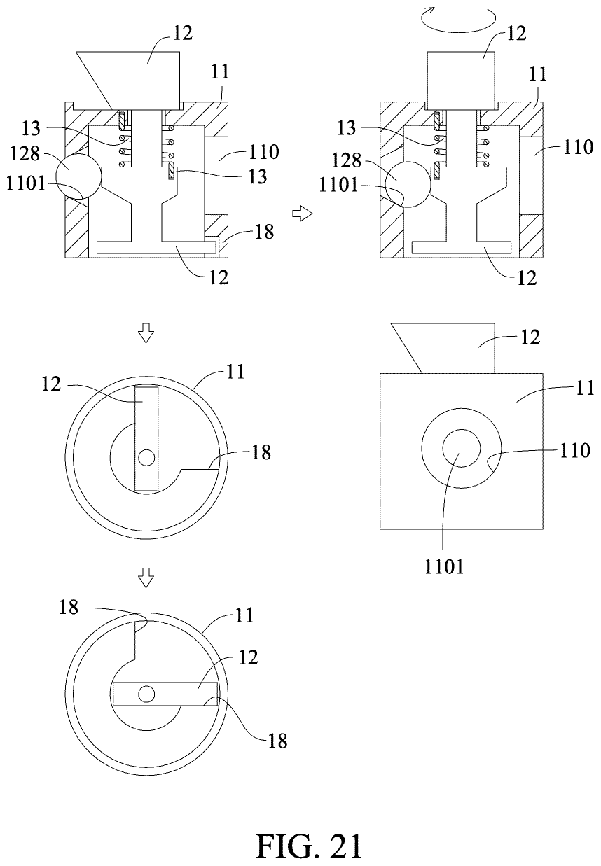

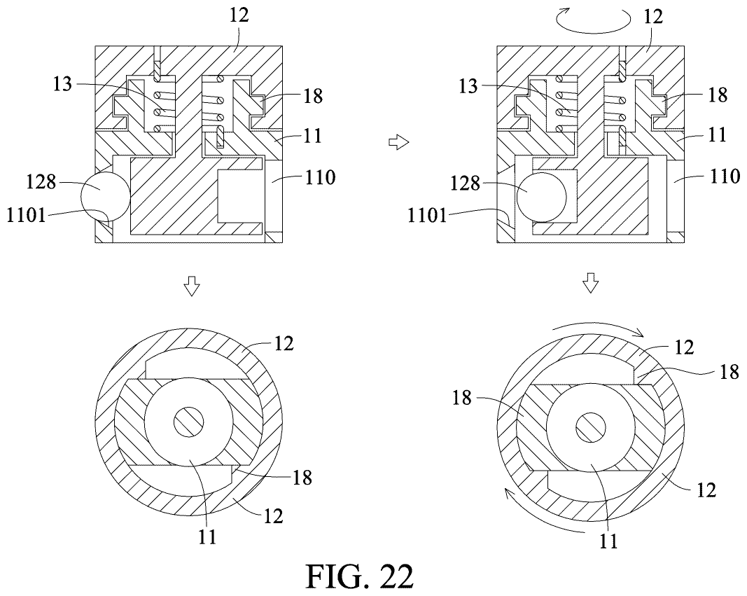

Referring to FIG. 21 and FIG. 22. In addition to the above embodiment, in an embodiment of the present disclosure, the difference from the above embodiment lies in that the body 11 is provided with an arrangement part 110 for assembling the fastening part 128, and the arrangement position 1101 is a position opposite to the arrangement part 110 or a position that is reachable by free fall. In this way, the present disclosure can better meet the actual application requirements.

In addition to the above embodiment, in an embodiment of the present disclosure, the difference from the above embodiment lies in that the elastic component 13 is a torsion spring, with two ends of the torsion spring respectively arranged on the body 11 and the abutment part 12, to allow the abutment part 12 to rotate elastically and abut against the fastening part 128, and enable the fastening part 128 to be located at a fastening position or a non-fastening position, where the body 11 (or the abutment part 12) may be provided with a limiting part 60 for limiting the abutment part 12 to be located at a fastening position or a non-fastening position of the fastening part 128. In this way, the present disclosure can better meet the actual application requirements.

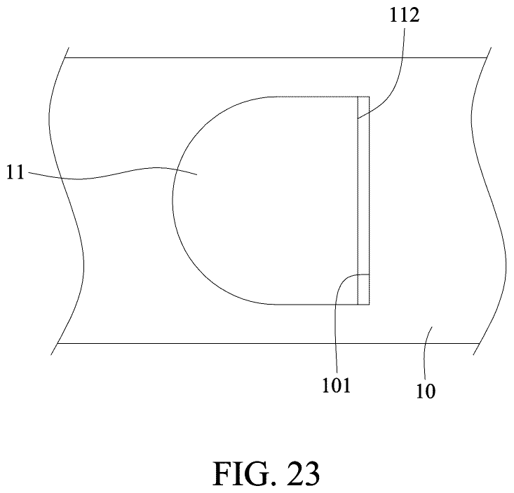

Referring to FIG. 23. In addition to the above embodiment, in an embodiment of the present disclosure, the difference from the above embodiment lies in that the body 11 is provided with an anti-rotating part 112, and the anti-rotating part 112 and the corresponding anti-rotating part 101 of the object 10 are used for preventing relative rotation between each other, so that the anti-rotating part 112 is configured to limit a direction of the body 11 and a fastening direction of the abutment part 12, or the anti-rotating part 112 is configured to limit directions of the body 11, the abutment part 12 and the object 10. In this way, the present disclosure can better meet the actual application requirements.

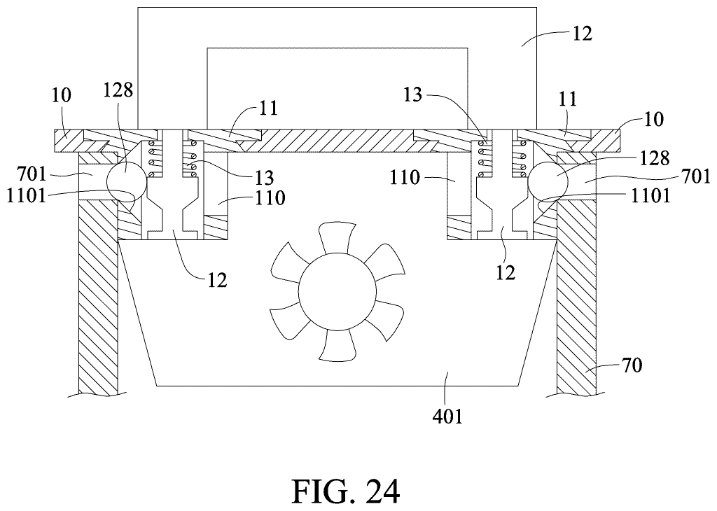

Referring to FIG. 24. In addition to the above embodiment, in an embodiment of the present disclosure, the difference from the above embodiment lies in that the body 11 is provided with an arrangement part 110, and the another object 70 (or the object 10) enters the body 11 through the arrangement part 110 and is fastened, interfered, locked or conducted by the abutment part 12. In this way, the present disclosure can better meet the actual application requirements.

In addition to the above embodiment, in an embodiment of the present disclosure, the difference from the above embodiment lies in that the another object 70 (or the object 10) may be a fastened body, a conductive body, a line, a fastening body, a spherical body, a rod body, an optical fiber, a cylindrical body or a plate body, so that the abutment part 12 is fastened to the fastened part 701 of the another object 70 (or the object 10) to achieve electric conduction. In this way, the present disclosure can better meet the actual application requirements.

In addition to the above embodiment, in an embodiment of the present disclosure, the difference from the above embodiment lies in that the abutment part 12 may be a fastening part, a cylindrical body, a threaded body, a protrusion body, a rod body, a recess body or a flat surface body, two ends of the elastic component 13 respectively abut against the body 11 and the abutment part 12, and the arrangement part 110 may be a hole, a groove, a trench or a space. In this way, the present disclosure can better meet the actual application requirements.

In addition to the above embodiment, in an embodiment of the present disclosure, the difference from the above embodiment lies in that a fan 401 (a power supply or a radiator) may be joined to the another object 70 through the abutment structure 1, and then fastening or electric conduction is achieved by using the abutment structure 1. In this way, the present disclosure can better meet the actual application requirements.

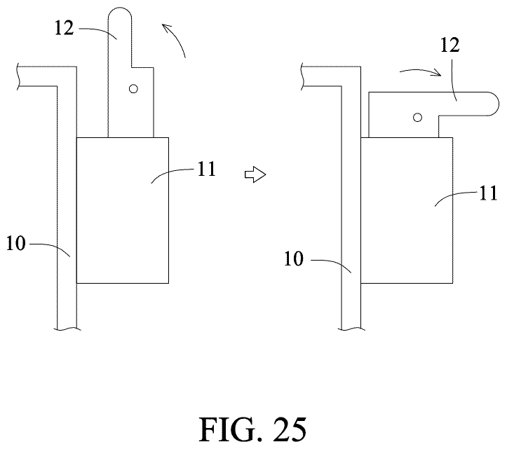

Referring to FIG. 25. In addition to the above embodiment, in an embodiment of the present disclosure, the difference from the above embodiment lies in that the abutment part 12 may be a handle (e.g., a toggle member, printed circuit board, case, integrated circuit, metal member or plastic member), the elastic component 13 is arranged between the body 11 and the abutment part 12, and the elastic component 13 is located on an inner side of the body 11.

When in use, the body 11 may be arranged on the object 10 and the abutment part 12 is toggled, so that the abutment part 12 rotates to reduce the height and further the abutment part 12 drives the fastening part 128 to fasten or unfasten.

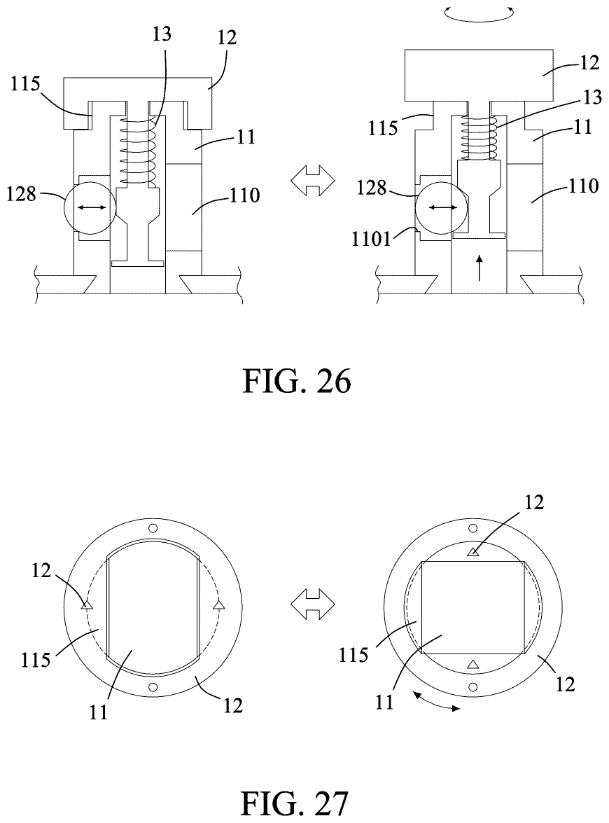

Referring to FIG. 26 and FIG. 27. In addition to the above embodiment, in an embodiment of the present disclosure, the difference from the above embodiment lies in that the body 11 is provided with an accommodating part 115, and the accommodating part 115 is configured to accommodate the abutment part 12 to reduce the height of the abutment part 12, or the abutment part 12 is raised and then rotationally arranged at a high position of the body outside the accommodating part, so that the abutment part 12 moves to switch the fastening part 128 and further the abutment part 12 drives the fastening part 128 to fasten or unfasten.

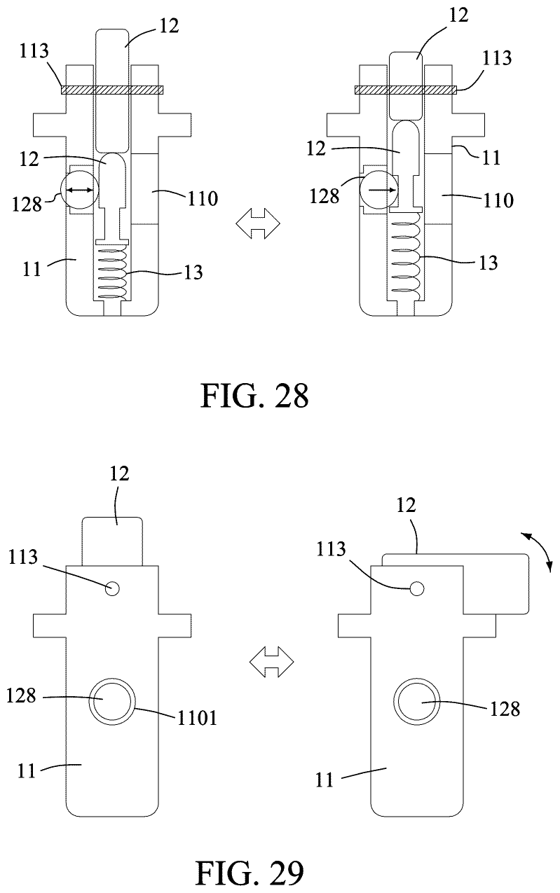

Referring to FIG. 28 and FIG. 29. In addition to the above embodiment, in an embodiment of the present disclosure, the difference from the above embodiment lies in that the number of the abutment parts 12 is two, and the abutment parts 12 abut against each other, one abutment part 12 is connected to the body 11 through a joining part 113, and one abutment part 12 rotates or moves to switch the fastening part 128, so that the abutment part 12 drives the fastening part 128 to fasten or unfasten.

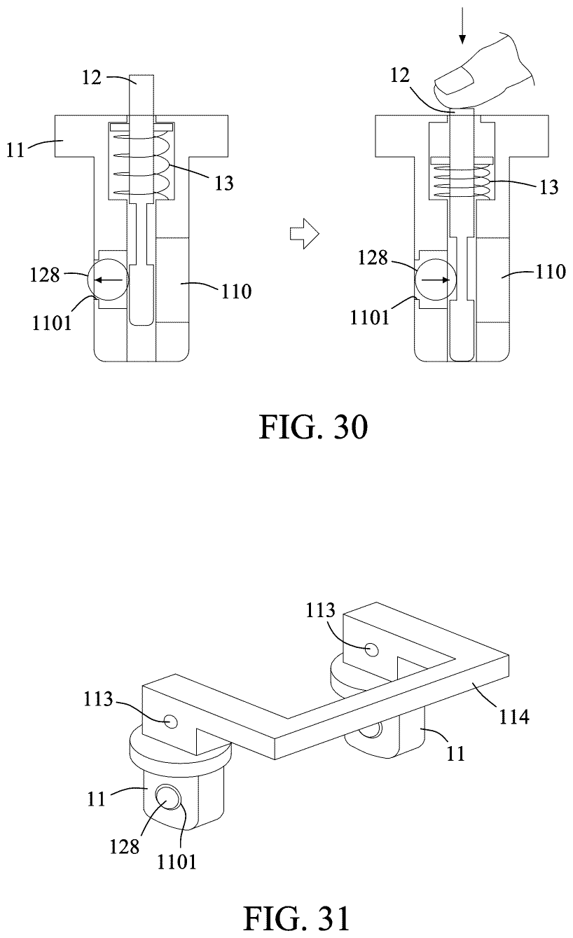

Referring to FIG. 30. In addition to the above embodiment, in an embodiment of the present disclosure, the difference from the above embodiment lies in that the abutment part 12 is moved (e.g., pressed) to undergo elastic movement with the elastic component 13, so that the fastening part 128 reaches an accommodating position of the abutment part 12 from an abutment position of the abutment part 12, enabling the fastening part 128 to move, and further the abutment part 12 drives the fastening part 128 to fasten or unfasten.

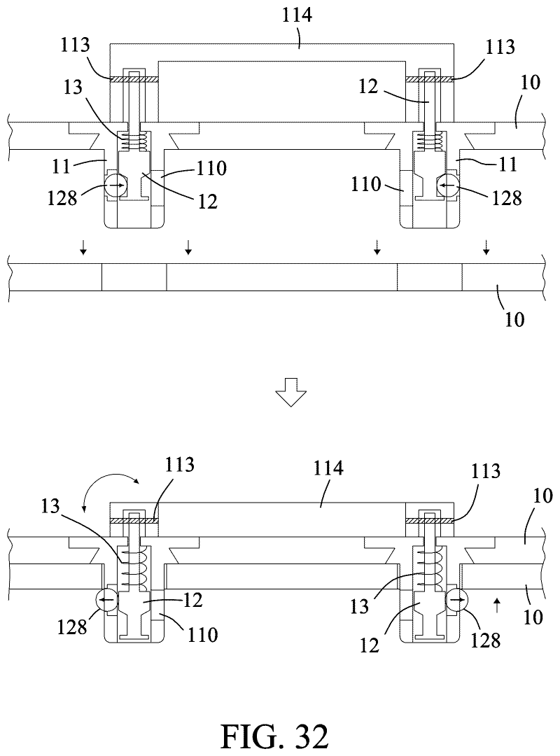

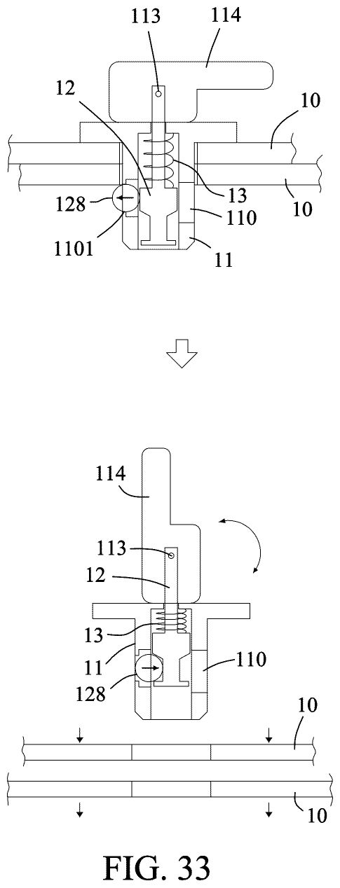

Referring to FIG. 31 to FIG. 33. In addition to the above embodiment, in an embodiment of the present disclosure, the difference from the above embodiment lies in that the number of the bodies 11, the abutment parts 12, the fastening parts 128 and the elastic components 13 may be respectively two, the abutment parts 12 are respectively connected to two ends of the handle part 114 through the joining parts 113, so that the handle part 114 can be rotated or moved by applying a force, causing the abutment parts 12 to synchronously drives the handle part 114, and further the abutment parts 12 respectively drive the fastening parts 128 to fasten or unfasten at least two objects 10.

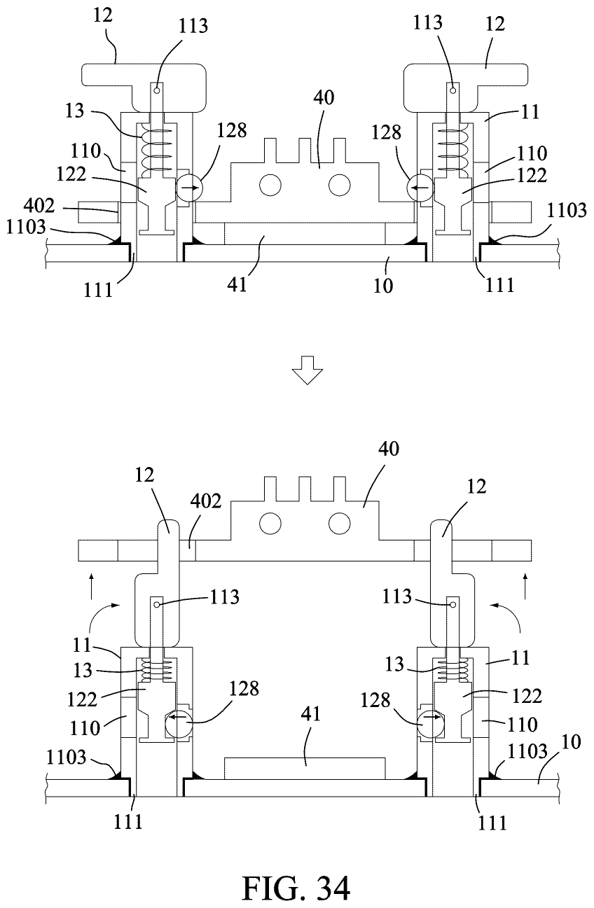

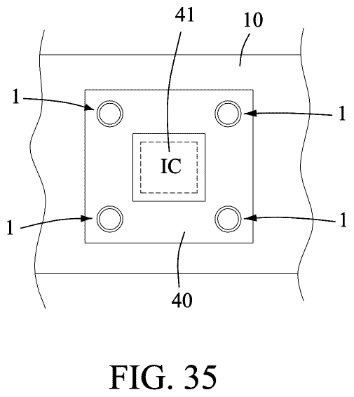

Referring to FIG. 34 to FIG. 35. In addition to the above embodiment, in an embodiment of the present disclosure, the difference from the above embodiment lies in that the abutment structure 1 is connected to a heat sink 40, and the heat sink 40 provides heat dissipation for a heating element 41.

In addition to the above embodiment, in an embodiment of the present disclosure, the number of the bodies 11, the abutment parts 12, the another fastening parts 122, the fastening parts 128 and the elastic components 13 may be respectively two, the connecting parts 111 of the bodies 11 are welded to the object 10, and the abutment parts 12 are respectively connected to the another fastening parts 122 through the joining parts 113, so that the abutment parts 12 can be rotated or moved by applying a force, thereby creating an unfastened state between the another fastening parts 122 and the fastening parts 128. This allows the heat sink 40 to penetrate through each body 11 a through hole 402, and then the abutment parts 12 are rotated or moved by applying a force, so that the another fastening parts 122 synchronously drive the abutment parts 12, and further the abutment parts 12 respectively drive the fastening parts 128 to fasten or unfasten the heat sink 40.

In addition to the above embodiment, in an embodiment of the present disclosure, the difference from the above embodiment lies in that the abutment structure 1 is arranged on the object 10 (e.g., the object 10 may be a printed circuit board or a conductive body) for the fastening part 128 to fasten the heat sink 40, where the object 10 is provided with the heating element 41 (e.g., the heating element 41 may be a chip or a conductive body), and the heat sink 40 provides heat dissipation for the heating element 41.

In addition to the above embodiments, in an embodiment of the present disclosure, the difference from the above embodiments lies in that the body 11 is connected to the object 10 by means of riveting, fastening, welding, locking, flaring, bonding, interference or blocking. Or, the body 11 and the object 10 are integrally formed. In this embodiment, the body 11 is welded to the object 10 through solder 1103 via the connecting part 111, where the object 10 is a printed circuit board or a chip.

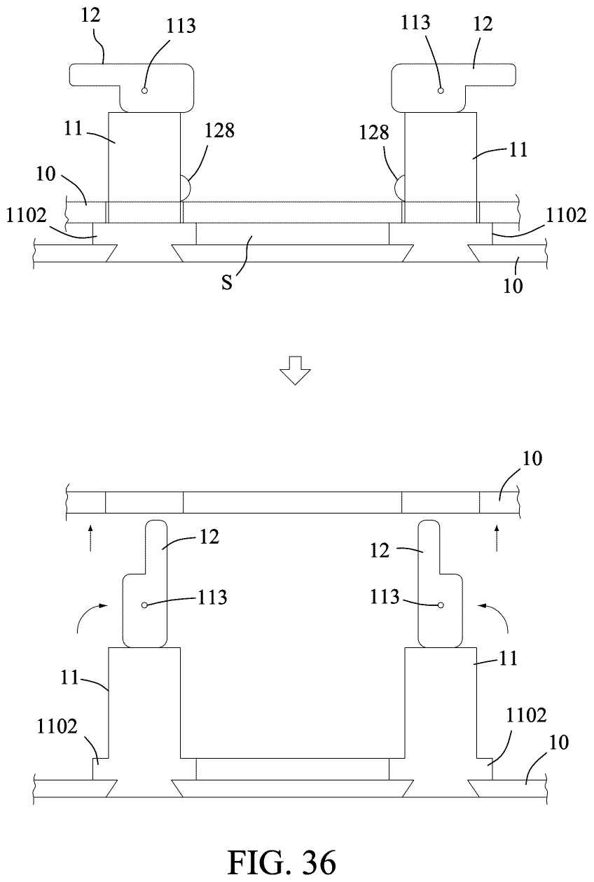

Referring to FIG. 36. In addition to the above embodiment, in an embodiment of the present disclosure, the difference from the above embodiment lies in that the abutment structure 1 is configured to connect at least two objects 10, and a gap space S is reserved between the two objects 10, or the two objects 10 are in close fit, or the two objects 10 are respectively a circuit board, a metal object or a plastic plate, or the two objects 10 are both metal objects, circuit boards or plastic plates, or the body 11 is provided with a shoulder 1102, and the gap space S is formed between the two objects 10 through the shoulder 1102. In this way, the present disclosure can better meet the actual application requirements.

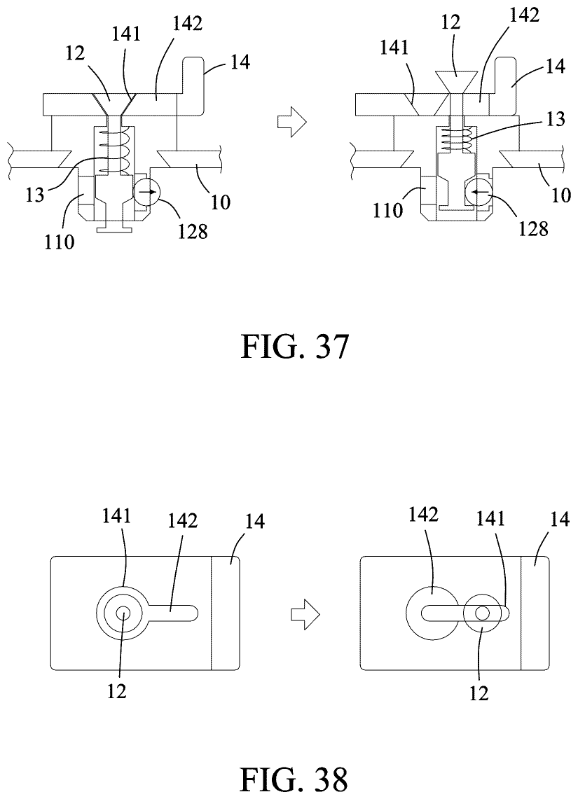

Referring to FIG. 37 and FIG. 38. In addition to the above embodiment, in an embodiment of the present disclosure, the difference from the above embodiment lies in that the abutment structure 1 may be provided with a moving part 14, or the moving part 14 is provided with a movement limiting part 141 and a channel 142, the movement limiting part 141 is communicated with the channel 142, the moving part 14 moves laterally to allow the abutment part 12 to lift from a low position of the movement limiting part 141 to a high position of the channel 142, the abutment part 12 is enabled to move to switch the fastening part 128 and further the abutment part 12 is enabled to drive the fastening part 128 to fasten or unfasten.

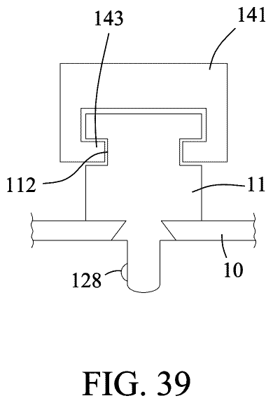

Referring to FIG. 39. In addition to the above embodiment, in an embodiment of the present disclosure, the difference from the above embodiment lies in that the abutment structure 1 is provided with a moving part 14, the moving part 14 is movably joined to the body 11, the body 11 is provided with an anti-rotating part 112, the moving part 14 is provided with another corresponding anti-rotating part 143, and the anti-rotating part 112 is abutted with the another corresponding anti-rotating part 143, so that the anti-rotating part 112 cooperates with the another corresponding anti-rotating part 143 to restrict a rotation position or an actuation direction of the moving part 14. In this way, the present disclosure can better meet the actual application requirements.

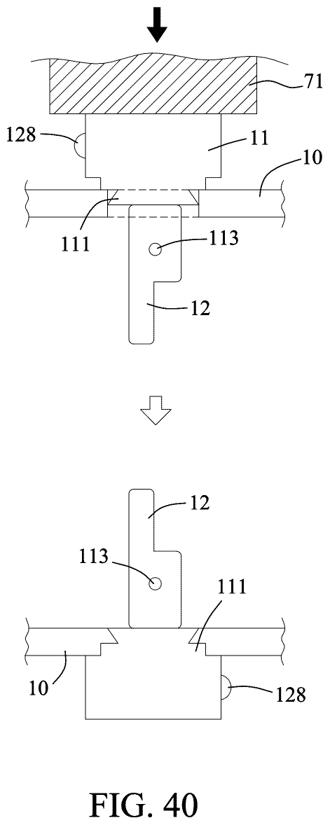

Referring to FIG. 40. In addition to the above embodiment, in an embodiment of the present disclosure, the difference from the above embodiment lies in that pressure is applied to the body 11 through a mold 71, so that the material of the object 10 flows into or enter the connecting part 111, thereby enabling the body 11 to be firmly joined to the object 10 through the connecting part 111. In this way, the present disclosure can better meet the actual application requirements.

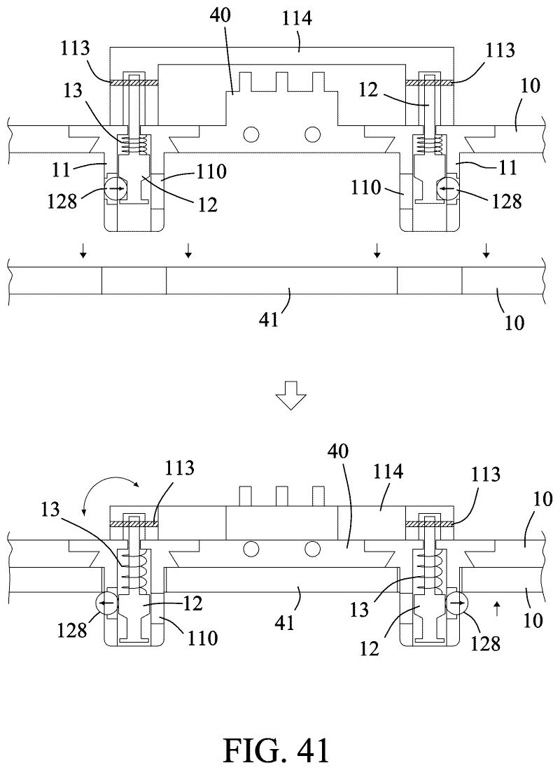

Referring to FIG. 41. In addition to the above embodiment, in an embodiment of the present disclosure, the difference from the above embodiment lies in that the abutment structure 1 is arranged on the heat sink 40 for the fastening part 128 to fasten the object 10 (for example, the object 10 may be a printed circuit board), where the object 10 is provided with the heating element 41 (for example, the heating element 41 may be a chip), and the heat sink 40 provides for heat dissipation for the heating element 41. In this way, the present disclosure can better meet the actual application requirements.

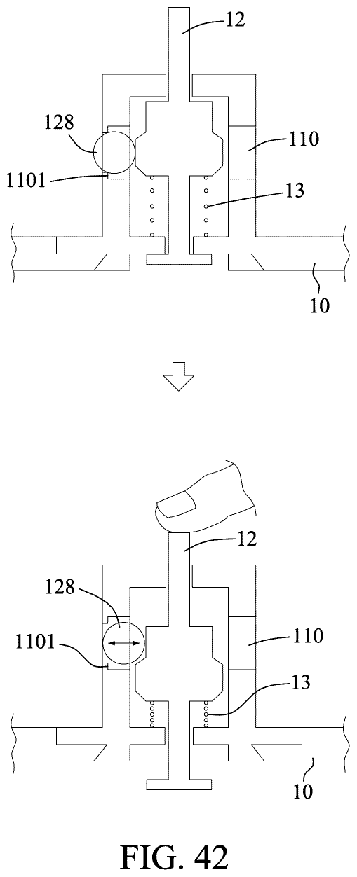

Referring to FIG. 42. In addition to the above embodiment, in an embodiment of the present disclosure, the difference from the above embodiment lies in that the body 11 is provided with an arrangement part 110 and an arrangement position 1101, the arrangement part 110 is larger than the arrangement position 1101 to enable the fastening part 128 to reach the arrangement position 1101 through the arrangement part 110 and be limited, or allow the abutment part 12 to abut against the fastening part 128, enabling the abutment part 12 to drive the movement or fastening of the fastening part 128. In this way, the present disclosure can better meet the actual application requirements.

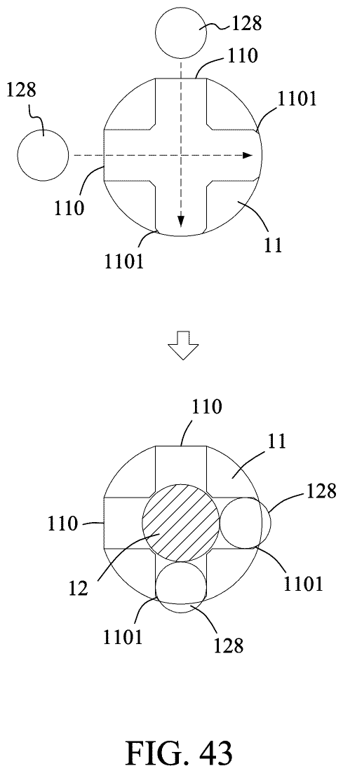

Referring to FIG. 43. In addition to the above embodiments, in an embodiment of the present disclosure, the body 11 has two arrangement parts 110, two fastening parts 128, and two arrangement positions 1101 to allow the two fastening parts 128 to reach the two arrangement positions 1101 through the two arrangement parts 110. In this way, the present disclosure can better meet the actual application requirements.

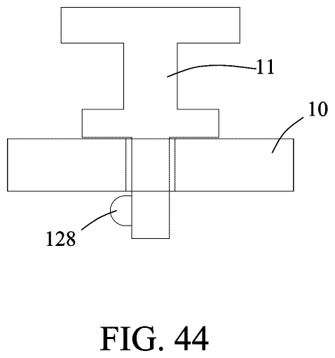

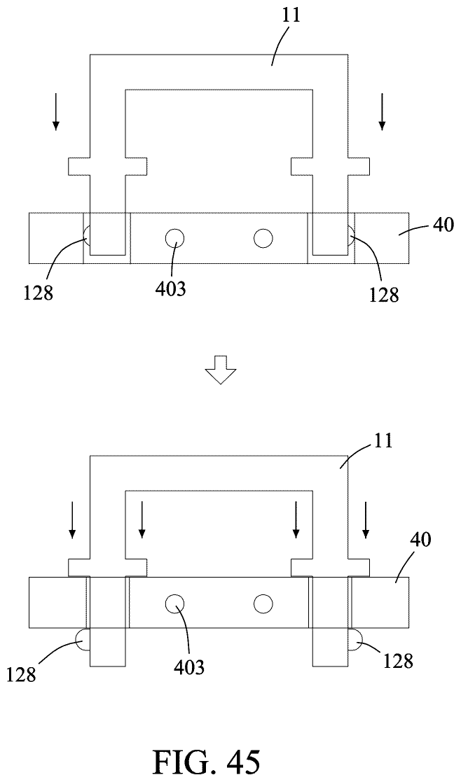

Referring to FIG. 44 and FIG. 45. In addition to the above embodiments, in an embodiment of the present disclosure, the fastening part 128 is configured to first retract inward to pass through the object 10 and the heat sink 40 and then protrude. For example, in the embodiment shown in FIG. 44, the fastening part 128 may be implemented on the object 10; and in the embodiment shown in FIG. 45, the fastening part 128 may be implemented on the heat sink 40. The heat sink 40 has a flow channel 403 for fluid to pass through for heat dissipation, and the body 11 may be a handle (as shown in FIG. 45). Therefore, the position of the fastening part 128 is fixed by the abutment part 12, so as to lift or operate the object 10 or the heat sink 40. The object 10 may be a printed circuit board, case, integrated circuit, metal member or plastic member. In this way, the present disclosure can better meet the actual application requirements.

The embodiments of the present disclosure described above only serve an illustrative purpose but are not restrictive of the claims of the present disclosure. While the present disclosure has been described by means of specific embodiments, numerous modifications and variations could be made thereto by those skilled in the art without departing from the scope and spirit of the present disclosure set forth in the claims.

What is claimed is:

1. An abutment structure, comprising:
a body;
at least one abutment part movably arranged on the body; and
a fastening part, the abutment part being configured to abut against the fastening part, or the abutment part being configured to control or drive the movement or fastening of the fastening part.

2. The abutment structure according to claim 1, wherein the body is provided with an arrangement part for allowing the fastening part to reach an arrangement position through the arrangement part.

3. The abutment structure according to claim 1, wherein the body is provided with an arrangement part, a limiting part, or a lifting part, or the limiting part restricts the abutment part, or the abutment part moves longitudinally to allow the fastening part to reach an arrangement position, or the lifting part is configured to rest against the rotated abutment part.

4. The abutment structure according to claim 1, wherein the abutment structure further comprises an elastic component, or the abutment part abuts against the fastening part, the body is provided with a limiting part, and the abutment part moves longitudinally or rotationally to allow the elastic component to be elastically limited by or elastically separated from the limiting part, or the abutment part drives the fastening part to reach an arrangement position, or the abutment part is provided with a releasing part, or is configured to rotationally restrict a restricted position or a released position of the fastening part through the releasing part.

5. The abutment structure according to claim 1, wherein the body is provided with an arrangement part configured to allow the fastening part to reach an arrangement position through the arrangement part and then the fastening part abuts against the abutment part, or the arrangement position is a position opposite to the arrangement part or a position that is reachable by free fall, or the arrangement position is a position that is reachable by the fastening part through the arrangement part by free fall.

6. The abutment structure according to claim 1, wherein the body is provided with a rotating part, the abutment part is provided with a corresponding rotating part, and the abutment part is rotated, so that the rotating part cooperates with the corresponding rotating part, or the abutment part or another fastening part spirally controls the movement of the fastening part.

7. The abutment structure according to claim 1, wherein the body is provided with a handle part, or the body is arranged on an object, or the fastening part is fastened to another object, or wherein the fastening part is a spherical body, an outer fastening body, a threaded body, a cylindrical body, an elastic fastening body, an inner fastening body, an inclined surface body or a curved surface body, or wherein the object or the another object is connected to a heat sink, or the heat sink provides heat dissipation for a heating element, or wherein the object or the another object is a main board, a metal body, a plastic body, a server, a transistor, a connector, a rail, a rack, a cabinet, a liquid cooled pipe or a liquid cooled joint.

8. The abutment structure according to claim 1, wherein the body is provided with an arrangement part for allowing the fastening part to enter or reach an arrangement position or a fastening position, the arrangement part is located at a position on a side of, above or below the body, or the fastening part is enabled to enter the body through the arrangement part for the abutment part to abut against the fastening part or for the abutment part to switch the fastening part, or the body is assembled with an elastic component to abut against the abutment part, or the body is assembled with an elastic component to abut against the body and the abutment part, or the abutment part is provided with a guiding part for guiding the fastening part to move, or the guiding part is an inclined surface, a curved surface, an arc surface, a stepped part, a recess, a protrusion or a flat surface, or the abutment part is provided with a limiting part for limiting a position of the fastening part or a position after movement, or wherein the number of the fastening parts is one, two or more, or wherein the fastening part reaches the arrangement position through the arrangement part by free fall, or wherein the arrangement position is smaller than the fastening part to restrict the fastening part from being separated from the body, or wherein the arrangement position is a hole, a groove, a trench or a space.

9. The abutment structure according to claim 1, wherein the body is provided with an anti-rotating part for preventing rotation relative to an object, or the abutment part is provided with another anti-rotating part for preventing rotation relative to the body, or the another anti-rotating part is configured to restrict a position or actuation of the abutment part, or the another anti-rotating part is configured to restrict a fastening direction, a fastening angle or a fastening position of the fastening part, or the body is provided with an anti-rotating part, or the anti-rotating part configured to restrict a direction of the body, or the anti-rotating part configured to restrict a fastening direction of the abutment part, or the anti-rotating part is configured to restrict directions of the body, the abutment part and the object, or the abutment structure is provided with a moving part, or the body is provided with an anti-rotating part, or the moving part is provided with another corresponding anti-rotating part, or the anti-rotating part cooperates with the another corresponding anti-rotating part to restrict a rotation position or an actuation direction of the moving part.

10. The abutment structure according to claim 1, wherein the abutment structure is provided with an elastic component, and the elastic component is a torsion spring, with two ends of the torsion spring respectively arranged on the body and the abutment part, to allow the abutment part to rotate elastically to abut against the fastening part, or enable the fastening part to be located at a fastening position or a non-fastening position.

11. The abutment structure according to claim 1, wherein the abutment structure further comprises an elastic component, or the elastic component is arranged between the body and the abutment part and located on an inner side or an outer side of the body, or wherein the body or the abutment part and the elastic component are integrally formed, or the elastic component is elastically deformable and fastened to a limiting part of the body.

12. The abutment structure according to claim 1, wherein the body is provided with an arrangement part, and an object enters the body through the arrangement part and is fastened, interfered, limited, locked or conducted by the abutment part, or wherein the object is a fastened body, a conductive body, a line, a fastening body, a spherical body, a rod body, an optical fiber, a cylindrical body or a plate body, or the abutment part is a fastening part, a cylindrical body, a threaded body, a protrusion body, a rod body, a recess body or a flat surface body, or the arrangement part is a hole, a groove, a trench or a space.

13. The abutment structure according to claim 1, wherein the abutment part is a toggle member, printed circuit board, case, integrated circuit, metal member or plastic member, or the body is a handle, or the abutment part is joined to another fastening part through another joining part, or configured to toggle the abutment part to control the another fastening part to be fastened to or unfastened from another object.

14. The abutment structure according to claim 1, wherein the body is provided with an accommodating part, and the accommodating part is configured to accommodate the abutment part to reduce the height of the abutment part, or the abutment part is raised and then rotationally arranged at a high position of the body outside the accommodating part to enable the abutment part to move to switch the fastening part.

15. The abutment structure according to claim 1, wherein the abutment part is moved to undergo elastic movement with the elastic component, so that the fastening part reaches an accommodating position of the abutment part from an abutment position of the abutment part to allow the fastening part to move.

16. The abutment structure according to claim 1, wherein the abutment structure is configured to connect at least two objects, and a gap space is reserved between the two objects, or the two objects are in close fit, or the two objects are respectively a circuit board, a metal object or a plastic plate, or the two objects are both metal objects, circuit boards or plastic plates, or the body is provided with a shoulder, and the gap space is formed between the two objects through the shoulder, or the abutment structure may be provided with a moving part, or the moving part is provided with a movement limiting part or a channel, or the movement limiting part is communicated with the channel, or the moving part moves laterally, or the abutment part is enabled to lift from a low position of the movement limiting part to a high position of the channel, or the abutment part is enabled to move to switch the fastening part.

17. The abutment structure according to claim 1, wherein the abutment structure is arranged on a heat sink for the fastening part to fasten an object, wherein the object is provided with a heating element, or the heat sink provides dissipation for the heating element, or wherein the object is a printed circuit board, or the heating element is a chip, or the object or the heating element is a conductive body; or the abutment structure is arranged on an object for the fastening part to fasten a heat sink, wherein the object is provided with a heating element, or the heat sink provides dissipation for the heating element, or wherein the object is a printed circuit board, or the heating element is a chip, or the object or the heating element is a conductive body.

18. The abutment structure according to claim 1, wherein the body is provided with an arrangement part and an arrangement position, the arrangement part is larger than the arrangement position to allow the fastening part to reach the arrangement position through the arrangement part, and the abutment part is configured to abut against the fastening part, or the abutment part is configured to control or drive the movement or fastening of the fastening part, or the arrangement part is a hole, a groove, a trench or a space.

19. The abutment structure according to claim 1, wherein the body has two arrangement parts, two fastening parts, and two arrangement positions to allow the two fastening parts to reach the two arrangement positions through the two arrangement parts.

20. The abutment structure according to claim 1, wherein the body has a connecting part configured to be welded, riveted, flared, fastened, or locked to or integrally formed with an object, or the object is a printed circuit board, a metal member, a plastic member or a heat sink.

21. The abutment structure according to claim 1, wherein the body has a connecting part configured to be welded to an object through solder, wherein the object is a printed circuit board or a chip.

22. The abutment structure according to claim 1, wherein the fastening part is configured to first retract inward to pass through an object and then protrude, so as to fix the position of the fastening part by the abutment part for lifting or operating the object, or the object is a heat sink, printed circuit board, case, integrated circuit, metal member or plastic member, or the body is a handle.
